(19) United States
(12) Patent Application Publication
(10) Pub. No.: US 2024/0063136 A1
(43) Pub. Date: Feb. 22, 2024

(54) INTEGRATED CIRCUIT DEVICE WITH ELECTRICALLY ACTIVE FIDUCIALS

(71) Applicant: Intel Corporation, Santa Clara, CA (US)

(72) Inventors: Haris Khan Niazi, Scottsdale, AZ (US); Yi Shi, Chandler, AZ (US); Adel Elsherbini, Chandler, AZ (US); Xavier Brun, Hillsboro, OR (US); Georgios Dogiamis, Chandler, AZ (US); Thomas Brown, Portland, OR (US); Omkar Karhade, Chandler, AZ (US)

(73) Assignee: Intel Corporation, Santa Clara, CA (US)

(21) Appl. No.: 17/891,560

(22) Filed: Aug. 19, 2022

(51) Int. Cl. H01L 23/544

(52) U.S. Cl. CPC H01L 23/544; H01L 2223/54426; H01L 2223/54473

(57) ABSTRACT

An integrated circuit (IC) device comprises an array comprising rows and columns of conductive interconnect pads. At least one optical alignment fiducial region is distinct from the array and comprises a fiducial pattern, wherein the fiducial pattern comprises a first group of pads contiguous to a second group of pads, and wherein a width of a space between nearest pads of the first and second groups is wider than the spaces between pads within each group.

### BACKGROUND

In electronics manufacturing, integrated circuit (IC) packaging involves bonding an integrated circuit (IC) die diced from a wafer onto another component in the package such as another die still on a wafer (or target wafer) or other package component. Optical imaging alignment systems use fiducials (or fiducial marks) that are detectable on the die to accurately align and bond the conductive pads on the die with corresponding pads on the other component, die, and/or wafer. After the die has been bonded, post-bond alignment testing is performed that images the fiducials again from the back (or blank) side of the bonded components to determine the accuracy of the alignment. This is often done with IR light because silicon is transparent to IR wavelengths. This post-bond alignment verification operation, however, often requires a metal-free keep out zone (KOZ) under the fiducial since metallization within a region of a fiducial reflects light from the optical system thereby interfering with a view of the fiducials. The use of a KOZ at fiducial areas of an IC die, however, reduces the total available conductive pad density of the die and significantly reduces the total usable active area of the die since traces, transistors, and other circuitry cannot occupy space in the KOZ either, resulting in reduction of the electrical capacity and/or signal transmission bandwidth (or efficiency) of the IC die.

### BRIEF DESCRIPTION OF THE DRAWINGS

The subject matter described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is a schematic diagram of a patterned X-Y view of an integrated circuit (IC) die with a conventional conductive pad array and fiducial region;

FIG. 2 is a schematic diagram of an X-Z cross-sectional side view of the conventional fiducial region in FIG. 1;

FIG. 3A is a schematic diagram of an X-Y patterned side view of an IC die with a conductive pad array and fiducial region according to at least one of the implementations herein;

FIG. 3B is a schematic diagram of an X-Z cross-sectional side view of the IC die of FIG. 3A shown being captured in an image according to at least one of the implementations herein;

FIG. 4 is a schematic diagram of a high magnification X-Y patterned side view of the fiducial region of FIGS. 3A and 3B and according to at least one of the implementations herein;

FIG. 5 is a schematic diagram of an image generated by an optical system viewing the fiducial region of FIG. 4 and according to at least one of the implementations herein;

FIG. 6A is a schematic diagram of an X-Y bottom view of a coiled antenna in a fiducial region according to at least one of the implementations herein;

FIG. 6B is a schematic diagram of another X-Y patterned side view of a coiled antenna in a fiducial region according to at least one of the implementations herein;

FIG. 7A is a flow chart of a method of manufacturing an electronic package according to at least one of the implementations herein;

FIG. 7B is a graph showing diffraction-limited resolution versus numerical aperture of an optical system according to at least one of the implementations herein;

FIG. 8 is a schematic diagram of an electronic post-bond pad misalignment measurement device according to at least one of the implementations herein;

FIG. 8A is a schematic diagram of a local test circuit according to at least one of the implementations herein;

FIGS. 9, 10A, 10B, 10C, and 11 are schematic diagrams showing X-Y top views of electrical ETOs in various states of misalignment according to at least one of the implementations herein;

FIG. 12 is a schematic diagram of an X-Y top plan view of a fiducial region of conductive pads of two arrays bonded together and with electrical ETOs according to at least one of the implementations herein;

FIG. 13 is a schematic diagram of X-Y top views of electrical ETOs of FIG. 12 each with a monitoring pad of a different size according to at least one of the implementations herein;

FIG. 14A is a flow chart of a method of post-bond pad misalignment measurement according to at least one of the implementations herein;

FIG. 14B is a flow chart of another method of post-bond pad misalignment measurement according to at least one of the implementations herein;

FIG. 14C is a schematic diagram of an X-Z cross-sectional side view of an example IC die package for testing capacitance according to at least one of the implementations herein;

FIG. 15 is a schematic diagram of an X-Z cross-sectional side view of an example IC die package with electrical testing overlays according to at least one of the implementations herein;

FIG. 16 is a schematic diagram of an X-Z cross-sectional side view of an example IC die package and frame electrical testing overlay according to at least one of the implementations herein;

FIG. 17 is a schematic diagram, of an X-Y patterned side view of an integrated circuit die according to FIG. 16;

FIG. 18 is a schematic diagram of an X-Z cross-sectional side view of an example IC die package with electrical testing overlays and a sacrificial redistribution layer (RDL) according to at least one of the implementations herein;

FIG. 19 is a schematic diagram of an X-Z cross-sectional side view of an example IC die package with electrical testing overlays and a wireless probing antenna according to at least one of the implementations herein;

FIG. 20 is a schematic diagram of an X-Z cross-sectional side view of an example IC die package with electrical testing overlays and photodiodes according to at least one of the implementations herein;

FIG. 21 is a functional block diagram of an electronic computing device according to at least one of the implementations herein; and

FIG. 22 illustrates a mobile computing platform and a data server machine employing an IC device comprising one or more IC dies with fiducials according to at least one of the implementations herein.

### DETAILED DESCRIPTION

Implementations are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary implementations. Further, it is to be understood that other implementations may be utilized and structural and/or functional changes may be made without departing from the scope of claimed subject matter. It should also be noted that directions and references (e.g., up, down, top, bottom, etc.) may be used merely to facilitate the description of features in the drawings and relationship between the features. Therefore, the following detailed description is not to be taken in a limiting sense and the scope of claimed subject matter is defined solely by the appended claims and their equivalents.

In the following description, numerous details are set forth. However, it will be apparent to one skilled in the art, that implementations may be practiced without these specific details. In some instances, well-known methods and devices are shown in block diagram form, rather than in detail, to avoid obscuring the implementations. Reference throughout this specification to “an implementation” or “one implementation” or “some implementations” refers to a particular feature, structure, function, or characteristic described in connection with the implementation that is included in at least one implementation. Thus, the appearances of the phrase “in an implementation” or “in one implementation” or “some implementations” in various places throughout this specification are not necessarily referring to the same implementation. Furthermore, the particular features, structures, functions, or characteristics may be combined in any suitable manner in one or more implementations. For example, a first implementation may be combined with a second implementation anywhere the particular features, structures, functions, or characteristics associated with each of the two implementations are not mutually exclusive.

As used in the description and the appended claims, the singular forms “a”, “an” and “the” are intended to include the plural forms as well, unless the context clearly indicates otherwise. It also will be understood that the term “and/or” as used herein refers to and encompasses any single associated listed item and any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular implementations, “connected” may be used to indicate that two or more elements are in direct physical, optical, or electrical contact with each other. “Coupled” may be used to indicated that two or more elements are in either direct or indirect (with other intervening elements between them) physical, optical, or electrical contact with each other, and/or that the two or more elements co-operate or interact with each other (e.g., as in a cause and effect relationship).

The terms “over,” “under,” “between,” and “on” as used herein refer to a relative position of one component or material with respect to other components or materials where such physical relationships are noteworthy. For example, in the context of materials, one material or structure disposed over or under another may be directly in contact or may have one or more intervening materials. Moreover, one material disposed between two materials may be directly in contact with the two materials or may have one or more intervening materials. In contrast, a first material or structure “on” a second material or structure is in direct contact with that second material/structure. Similar distinctions are to be made in the context of component assemblies where a first component may be “on” or “over” a second component.

As used throughout this description, and in the claims, a list of items joined by the term “at least one of” or “one or more of” can refer to any combination of the listed terms. For example, the phrase “at least one of A, B, or C” can refer to A; B; C; A and B; A and C; B and C; or A, B, and C.

In the manufacture of IC devices, one or more “device layers” are fabricated during front-end-of-line (FEOL) processing. Device layers include active or passive devices, or devices of both types. In some implementations, the active devices are field effect transistors (FETs). Active and passive devices in a device layer are examples of “metallization features.” In addition, one or more “metallization layers” are fabricated during back-end-of line (BEOL) processing. Active and passive devices of a device layer are interconnected into circuitry with metal structures within one or more metallization layers. A metallization layer may comprise any number of metal structures separated by inter-layer dielectric (ILD) material. The metal structures in a metallization layer are more examples of “metallization features.”

In electronics manufacturing, IC packaging is a stage of the manufacturing process where an IC that has been fabricated on a die or chip comprising a semiconducting material is coupled to a supporting case or “package” that can protect the IC from physical damage and support electrical contacts suitable for further connecting to another IC die, a package substrate, and/or a host component, such as a printed circuit board (PCB). In the IC industry, the process of fabricating a package is often referred to as packaging, or assembly.

The IC industry is continually striving to produce higher computational performance in smaller packages for use in various electronic products, such as computer servers, portable computers, electronic tablets, desktop computers, and mobile communication handsets. High performance computing products often now include one or more microelectronic packages that contain various combinations of semiconductor tiles, chips, chiplets, and dies that are integrated into one functional unit. These composite, or heterogeneous, IC device structures may include tiles, chips, chiplets, or dies created using diverse technologies and materials. The tiles, chips, chiplets, or dies may be stacked vertically, placed horizontally, or both. Connections between different devices may employ a variety of technologies, including direct bonding. Chiplets, rather than monolithic dies, disaggregate the circuits. The chiplets are electrically coupled by interconnect bridges. The term “chiplet” is used herein to refer to a die that is part of an assembly of interconnected dies forming a complete IC in terms of application and/or functionality, such as a memory chip, microprocessor, microcontroller, commodity IC (e.g., chip used for repetitive processing routines, simple tasks, application specific IC, etc.), and system-on-a-chip (SoC). In other words, the chiplets are individual dies (or IC dies) connected together to create the functionalities of a monolithic IC. By using separate chiplets, each individual chiplet can be designed and manufactured optimally for a particular functionality. For example, a processor core that contains logic circuits might aim for performance, and thus might require a very speed-optimized layout. This has different manufacturing requirements compared to a USB controller, which is built to meet certain USB standards, rather than for processing speed. Thus, by having different parts of the overall design separated into different chiplets, each one optimized in terms of design and manufacturing, the overall yield and cost of the combined chiplet solution may be improved.

The connectivity between these chiplets is achievable by many different ways. For example, in 2.5D packaging solutions, a silicon interposer and Through Silicon Vias (TSVs) connect dies at silicon interconnect speed in a minimal footprint. In another example, called Embedded Multi-Die Interconnect Bridge (EMIB), a silicon bridge embedded under the edges of two interconnecting dies facilitates electrical coupling between them. In a three-dimensional (3D) architecture, the chiplets are stacked one above the other, creating a smaller footprint overall. Typically, the electrical connectivity and mechanical coupling in such 3D architecture is achieved using TSVs and high pitch solder-based bumps (e.g., C2 interconnections). The EMIB and the 3D stacked architecture may also be combined using an omni-directional interconnect (ODI), which allows for top-packaged chips to communicate with other chips horizontally using EMIB and vertically, using Through Mold Vias (TMVs) which are typically larger than TSVs.

In some implementations that use chiplets, a composite chip may have a fill dielectric layer over BEOL a metallization stack. A fill dielectric layer may fully surround chiplet sidewalls, embedding a chiplet within dielectric material. A fill dielectric may stabilize and strengthen the composite die structure 100, and/or provide a platform for higher BEOL metallization layers. In some implementations, a fill dielectric layer comprises an inorganic dielectric material, such as, but not limited to, amorphous and polycrystalline silicon oxides, in some cases having a higher k than ILD materials. In some other implementations, a fill dielectric layer comprises an organic material, such as, but not limited to, epoxy resins and epoxy resin composites. Vias may extend through a fill dielectric layer. Vias may also interconnect upper BEOL metallization levels or embedded devices to a level M₄ and lower metallization levels. Vias may route power and/or signals to device layer 104. The IC dies discussed below can be chiplets.

A variety of manufacturing challenges exist at the IC packaging stage of electronics manufacturing. Some manufacturing challenges arise when an IC die is stacked vertically on, or placed horizontally with, another IC die in an IC package. The IC package examples described herein may be manufactured, in part, with bonding techniques in which metal features such as conductive pads surrounded by an insulator of one IC die are directly fused to metal features surrounded by an insulator of another die. When both the metal features and the insulators are fused, the resultant composite structure comprises a hybrid bonded interface of both metallurgically inter-diffused metals and chemically bonded insulators. Prior to bonding, each IC die may be fabricated in a monolithic process separate from that of the other IC die. As such, an IC die may utilize the same or different semiconductor device fabrication technologies as the IC die to which it is bonded. These bonding techniques may be referred to as “hybrid” or “direct” bonding where the bonded metal form hybrid bonding interconnects (HBIs) that avoid the use of solder balls. Herein, “hybrid direct bonds” may comprise die-to-die (DTD) interconnects with sub 10 micrometer pitch. In other words, the separation between any two hybrid direct bonds, and in turn the conductive pads of the array, is less than or equal to 10 micrometers except for the fiducial region as described herein.

Direct bonding enables tighter pitches between interconnects on the surface of an IC die than the pitches used in traditional bonding methods. For example, pitches may be less than 9 μm while the conductive pad width may be 200 nm with a margin of error at three sigma. Failure to accurately align the electrically conductive interconnects on the respective IC die can result in an interconnect on a die not having sufficient contact with a corresponding interconnect of another die, resulting in a device that does not operate correctly or at all. Accordingly, the tighter die pitch used in direct bonding can require significantly higher placement accuracy during bonding operations as compared with traditional bonding methods. This may be referred to as pre-bond overlay measurement performed by using microscopic light-based optical (visible light wavelength) cameras to perform the alignment during pre-bonding.

To verify the accuracy of bonding alignment after direct bonding is employed, a post-bond inspection also may be performed. The direct bond interface is at an exposed outer surface of an IC die and an exposed outer surface of another IC die which may still be or part of a wafer. Typically, the fiducials used for alignment of the IC die and wafer are at the direct bond interface, e.g., on the two opposing outer surfaces as well. The fiducials also could be in any of the interior layers of the IC die and/or wafer adjacent to the outside surfaces. Bulk silicon is transparent at various wavelengths used in near infrared (NIR) imaging. Thus, after bonding, NIR imaging at surfaces opposite the outer surfaces of the IC die and wafer may be used to view the fiducials used for alignment whether the fiducials are on the outside surfaces or within the interior of the IC die and wafer.

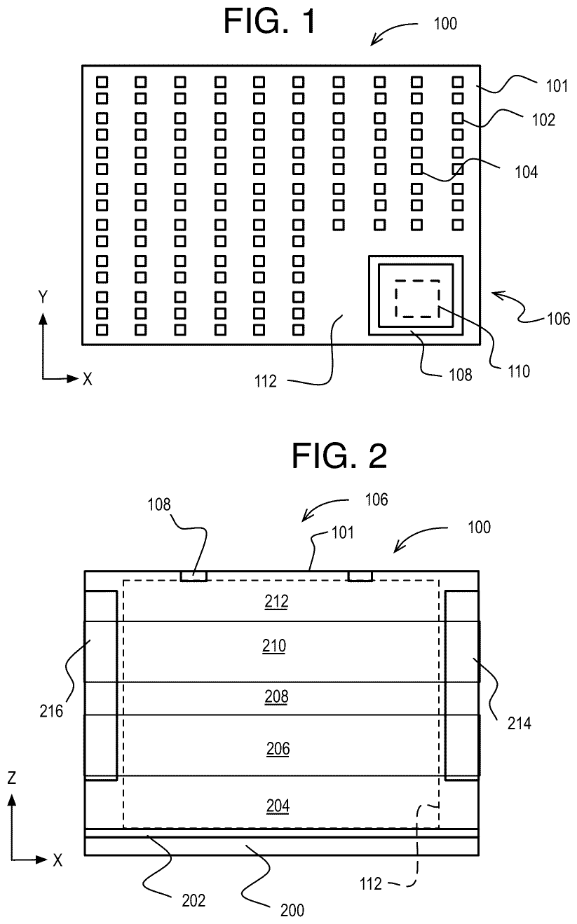

Referring to FIGS. 1-2 for example, since metal can reflect NIR light from an alignment system projector, this can block or obscure the view of the fiducials so that an NIR image of the fiducials cannot be captured. The degree of blockage depends on, among other things, the density of metal within the metallization level. Thus, a metal free “keep out zone” (KOZ) is often used at the fiducials. For example, an IC die 100 has a patterned surface 101 with an array 102 of interconnect conductive pads 104 that may be arranged in rows and columns. The entire array 102 is not shown. Each corner of the array 102 may be next to a fiducial or fiducial region 106 with a fiducial mark or pattern 108 here being a metallization formed in a square frame. The fiducial 106 on the IC die 100 is shaped to concentrically align with a fiducial (or fiducial pattern) 110 on another die being bonded to IC die 100.

The fiducial region 106 also may have a KOZ column, here being a metal free column 112 (FIG. 2). The KOZ column 112 may extend all the way down to one or more Si substrate layers 200 and 202 for NIR light to pass through without being absorbed and/or attenuated so that an NIR image of the fiducial 108 is clear. The KOZ column 112 may be surrounded by multiple metal of metallization layers 204, 206, 208, 210, and/or 212 that wrap around the KOZ column 112 shown at sides 214 and 216, and without entering directly beneath the fiducial 108 on the first surface 101. Thus, no conductive pads or metal traces can be placed within the KOZ column 112, and no transistor functionality is present in this region.

For die to wafer (D2 W) bonding, and for a full loop die, as the size of the die decreases, these metal free columns significantly reduce the active area of the die thereby decreasing the efficiency of the die. As an example, for 9 μm HBI pitch with an 80 μm×80 μm KOZ, a potential 79 connections per fiducial are sacrificed (or 79*4=316 connections per die assuming fiducials in all four corners). Furthermore, when pitch is scaled down to 1 μm with the same KOZ, 6400 connections are sacrificed per fiducial. Lastly, fiducials also introduce a pattern and/or density die surface variation from the relatively smooth continuous surface of the exposed array pads. This results in topography variations at die edges after chemical mechanical planarization (CMP), which negatively affects bonding.

One conventional technique to limit the extent of misalignments at the interconnects is to decrease the size of the fiducial. This allows more active interconnects in the vicinity of the fiducial. The smaller fiducial, however, increases the difficulty for an optical alignment system and bond tools to accurately align the dies while placing the dies on a target wafer during a D2 W bonding for example. When fiducials become too small, the bonding tool cannot resolve or see the fiducials. Also, since the KOZ extends throughout a stack of layers on a die anyway, such fiducials with a KOZ column still reserves space that could have been used for a significant amount of active area or to be use to increase flexibility for metallization layout.

To resolve these issues, electrically active interconnect pads themselves are used to form at least one fiducial pattern on an IC die for a pre-bond overlay (or alignment of pads). The electrically active pads can be imaged with present optical toolsets with limited resolution. Specifically, the disclosed fiducial pattern has electrically active interconnect pads with spacing between the pads that is less than a diffraction-limited resolution of a pre-bonding overlay alignment optical system used to capture images of the fiducial pattern. Thus, the system cannot distinguish these neighboring pads as separate, and will see a group of the fiducial pads as one solid object. In other words, with very small objects being imaged by an optical system, the diffraction-limited resolution is the minimum distance between objects required to be able to detect the segmentation between the two objects to show two separate objects in an image. Otherwise, the two objects will appear as one object. To apply this to the IC die, the fiducial pattern can be created by having groups of pads with a space between the groups defined by nearest or boundary pads of the two different groups. This space has a width defined between outer edges of the two nearest pads that are facing each other from different groups. The width of the space should be at least the diffraction-limited resolution of the optical system so that the different groups appear separate in the image and to be used to capture an image of the fiducial pattern for pre-bond alignment. The spacing between pads within the same group should be less than the diffraction-limited resolution so that they appear as one solid shape. So arranged, the groups will each individually then appear as a single continuous shape while lines between the groups in the fiducial pattern can be created by defining the width of the space to be at least the diffraction-limited resolution of the optical system. When rows and columns of the pads are continued from the main array and into the fiducial region, it can be easy to see that a fiducial pitch between the nearest or boundary pads of two contiguous groups, and across the space in the direction of the width of the space, is set at the diffraction-limited resolution plus the width of a single pad (assuming the nearest pads have the same width), and usually will be longer than the pitch between pads within the same group (assuming all pads have the same size).

With such spacing and pitch between pads, the pad density of the IC die can be increased substantially. Also, the segmentation described, along with similarity among neighboring features among pads, enables increased CMP uniformity thereby providing more ideal, efficient, bonding conducive topography.

Post-bond pad misalignment measurement may be performed after two dies (or die and another electronic device) with the fiducial regions described above have been bonded together. The bonding may be for D2 W, W2 W bonding, and so forth. The post-bond testing or measurement disclosed herein can be performed without the use of IR imaging that requires a KOZ. Instead, as a scalable solution for small interconnect pitches, electrical probing misalignment testing may be performed by using post-bond pad misalignment measurement device or system that uses on-board electrical testing overlays (ETOs) with local test circuits to determine when misaligned pads of two bonded fiducial regions are in contact. Specifically, the local test circuits electrically activate the ETOs in pad arrays of the two bonded dies to determine pad misalignment between the pad arrays. By one approach, each ETO has an alignment monitoring pad (referred to herein as top, upper, or monitoring pads) on one die array corresponding to an electrical testing group pattern of pads (referred to herein as bottom, lower, or pattern pads) on the other die pad array. The monitoring pad of each ETO is a different size so that nominal horizontal offsets from the monitoring pad to the pattern pads in plan view (or X-Y view) is different in each ETO. When the monitoring pad is in contact with one or more pattern pads in an ETO, the electrical voltage and current levels of the pads, and in turn resistance and/or capacitance, can be used to determine a direction and amount (or magnitude or distance) of misalignment of the pads from the two bonded arrays.

Since this electrical probing can eliminate the need for IR imaging alignment, the need for a metal-free KOZ is eliminated and this solution can be used to reclaim not only die surface area for connections at the die surface, but also much or the entirety of the dielectric stack volume or column underneath the fiducial pattern. In this case, additional metal of metallization layers may be placed anywhere under the fiducial region including under the spaces between the pad groups described above. Thus, by replacing the use of IR image fiducials and KOZs for post-bond alignment measurement with the use of electrically active pads as the fiducials, the IC dies now may have capacity for a significant number (potentially thousands) of additional connections per die. Thus, this solution provides developers a significant increase in flexibility for arranging the metallization on the IC dies, as well as tapping into transistor functionality in previously inaccessible regions of the die.

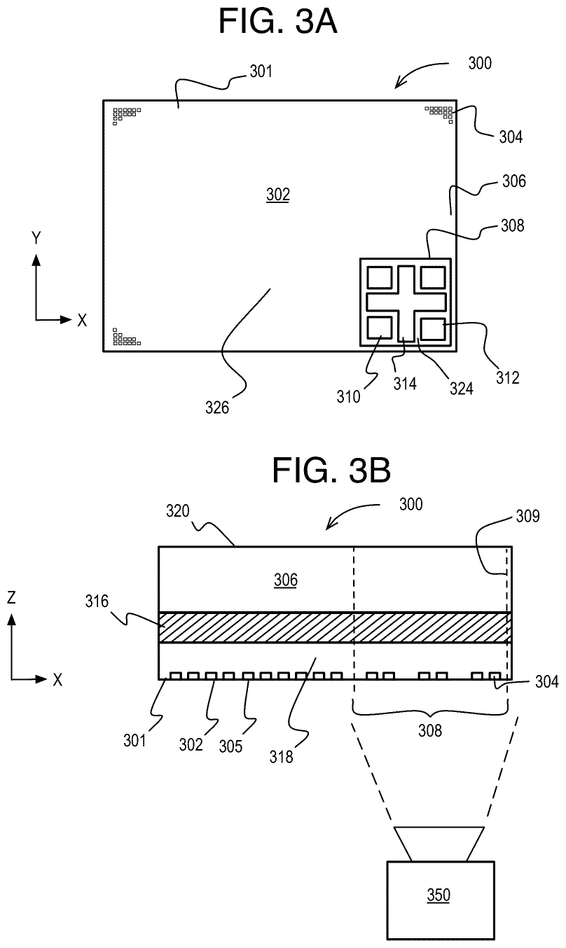

Referring to FIGS. 3A-3B for example, an integrated circuit (IC) die 300 has a patterned surface 301 with a conductive pad array 302, which may be referred to as a main array where pads 304 are arranged in rows and columns, and each pad 304 has a bonding surface (whether a bottom surface here or a top surface) to be bonded to pads of another array, and by one form bond directly to pads of the other array, such as with HBI/hybrid bonding. The IC die 300 also has a fiducial region 308 coplanar, or generally coplanar, to the array 302 and that is also formed by the pads 304. The pads 304 may or may not be the same in both the array 302 and fiducial region 308 in bonding pad size and shape. As described herein for some implementations, the fiducial region 308 may be considered to have one or more separate pad arrays from the main array 302, but in some descriptions below the fiducial region 308 also or instead may be considered a part of the array 302.

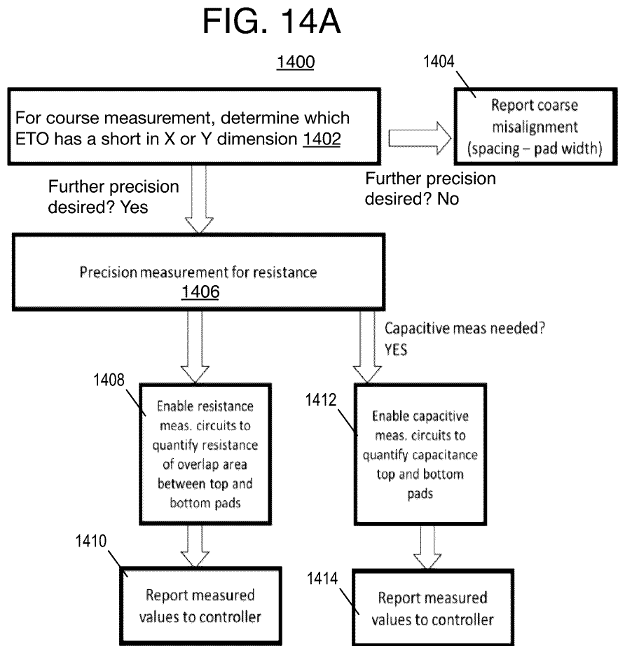

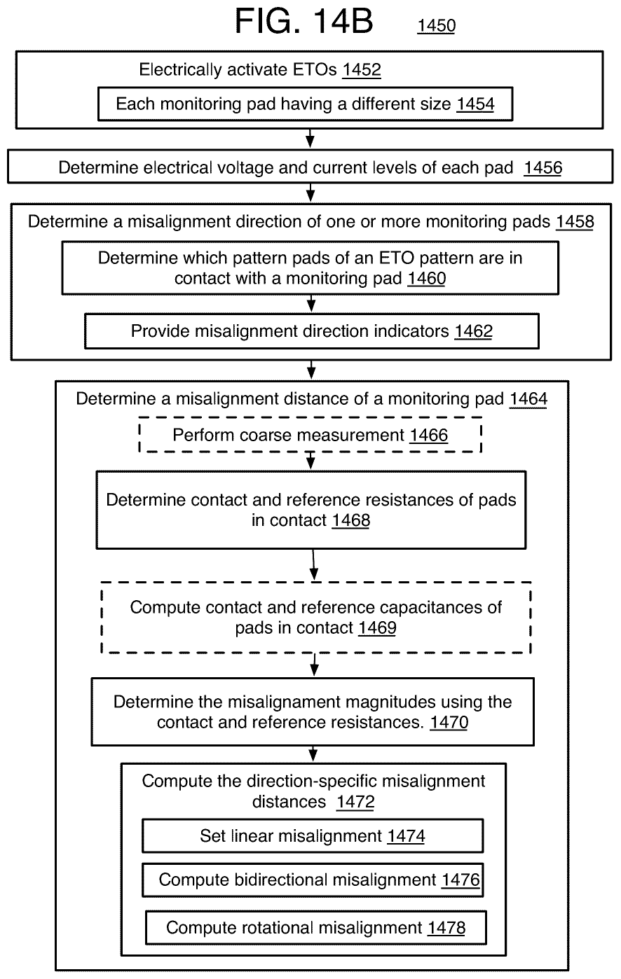

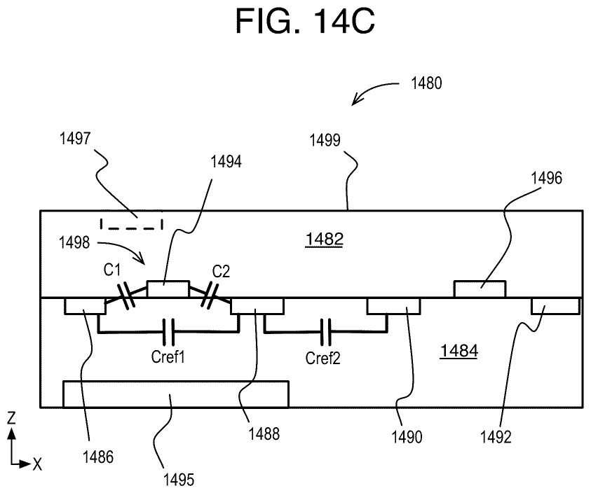

The pads 304 may be of uniform structure such as with an array of HBIs. Otherwise, the pads 304 may be part of any interconnect features that can be arranged in a uniform pitch array of metal pads where the pads are contacts, metallization features, or other interconnect features. The pads 304 also may align with corresponding pads on an electronic device (not shown here but see FIGS. 14-19 and 21) to be bonded to the IC die 300.

Such an electronic device being bonded to IC die 300 may have the same or similar structure as IC die 300 except with a second conductive pad array in a mirrored arrangement relative to array 302 to bond the two arrays together. By one form, the electronic device is another IC die not yet diced from a wafer (or to remain permanently on the wafer or part of the wafer to become a component of a package) so that the bonding may be characterized as die-to-wafer (D2 W) bonding. Such a wafer may have many such electronic devices where a different IC die is being mounted to different electronic devices (or different dies) formed by or on the wafer. Otherwise, if the IC die 300 is not diced yet, W2 W bonding may be performed. Otherwise, the electronic device may be a package substrate or any specific component, device, or layer on such a package substrate, or a host component such as a system on a chip (SoC), printed circuit board (PCB), motherboard, and so forth. By one form, the IC die 300 may be a chiplet being bonded to a host IC die. The electronic device is not limited as long as an array of conductive pads for direct bonding, such as with HBIs, is provided. Many variations are contemplated.

As shown in FIG. 3B, the IC die 300 may have stacked a dielectric material 306 that is a bulk Si substrate, at least one metallization layer 316, and a dielectric layer 318 with both dielectric material and one or more embedded metallization layers (not shown) parts of which couple to pads 304 of the array 302. By one form, the pads 304 extend to have bonding interface surfaces 305 be coplanar with the patterned surface 301 of the dielectric layer 318. The dielectric material of the layer 318 may be between the pads 304 in this case. The bulk Si 306 forms a back or here blank surface 320 of the IC die 300. Alternatively, conductive pads 304 may extend outward of the patterned surface 301. By one form, an IC die 300 with 200 nm×200 nm pad on a 4 mm×4 mm die may have about 400 million interconnects.

In some implementations, the die metallization layer 316, as well as other metallization in the dielectric layer 318, may have one or more device layers and/or one or more metallization features such as transistors, inductors, capacitors, and resistors, as well as traces, vias, and so forth. In various implementations, the metal in the metallization layer 316 extends beneath (or over) the fiducial region 308 on the IC die 300 and through a vertical column 309 forming a volume of the fiducial region as shown by the dashed lines. This volume of the fiducial region 308 no longer needs to be reserved as a KOZ since IR imaging is not used in this fiducial region. By one form, no limit exists for the placement of metal under the fiducial region 308 due to fiducial-based bonding alignment as described herein. Metal of one or more metallization layers 316 may horizontally extend under (or actually over in FIG. 3B) part or the entire fiducial region 308 including under spaces between groups of pads 304 as described herein, and may be stacked within the fiducial region volume or column 309 in as many metallization layers as desired with regard to the fiducial image capture.

The fiducial region 308 is near at least one corner of the array 302, and by one example form, may have hundreds of pads. It will be appreciated that the fiducial region 308 could be near, or form, each corner of a rectangular main array 302, may be spaced along sides of the array, or may be positioned at other locations within the array as desired. The fiducial region 308 has an example fiducial pattern 310 formed by the pads 304, and by one example, by extending the rows and columns of pads 304 into the fiducial region 308, although this arrangement need not always be used. The example fiducial pattern 310 has four groups 312 of an array of pads 304 each with spacing between the pads within the same group that is not large enough to segment the pads in an optical image. The fiducial pattern 310 also has a large group that is a cross or other shape 314. Each of the groups is segmented from another group by using a spacing that is at least the diffraction-limited resolution of the optical system used to take images of the fiducial pattern, thereby having the groups 312 or 314 each form a fiducial or fiducial mark of the fiducial pattern 310. It also will be appreciated that the outer boundary of the array 302, the outer boundary of the fiducial region 308, groups 312 and/or 314, or any other parts thereof can be many different shapes and need not always be the same shape. By one form, any of these (array, group, region) may be hexagonal or other desired shapes as long as the spacing between pads remains as described herein. The shapes of the arrays or groups or regions may be selected for convenience or efficiency for the manufacturing process and/or specifically for a bonder tool vision system.

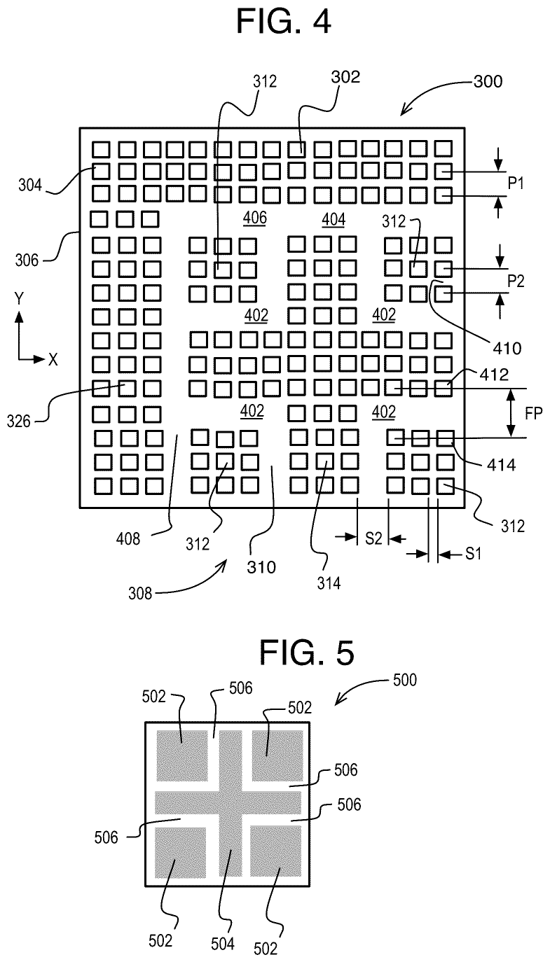

To explain further, a Rayleigh resolution or similar criterion is used to set the minimum width of a space between pads from two different groups 312 and 314 as well as the maximum width of a space between pads of the same group 312 or 314. This in turn defines a fiducial pitch FP (FIG. 4) between pads of different groups that is usually larger than a first pitch P2 (FIG. 4) between the pads in the same group. Such parameters create a visible light wavelength image that shows the fiducial pattern 310. Specifically, diffraction in an optical system (also referred to herein as an optical alignment tool) 350 places a fundamental limit on the amount that light can be focused. Therefore, light cannot be focused through a lens into an infinitesimally miniscule spot, but rather a finite diameter determined by the wavelength of light and the numerical aperture of an optical system. Resolution here refers to the ability of a system to distinguish two closely spaced points in object space as two distinct finite spots in image space. If the points in object space are too close together, then the finite spots in image space will blend together, and the image will be unresolved. When the spots are a sufficient distance apart, they are resolved or in other words, the segmentation into two different spots becomes visible in a visible light wavelength based image. The diffraction-limited resolution of an optical system is given by:

$$Res = \frac{0.61 λ}{NA} \qquad ( 1 )$$

where Res is the resolution (minimum separation of points resolvable also referred to as the resolution limit or diffraction-limited resolution), 2 is the wavelength of light used (in microns), and NA is the numerical aperture of the optical system to be used to detect and image the fiducial region for pre-bond pad alignment.

Thus, to apply equation (1) to the fiducial pattern 310 disclosed herein using the relatively low resolution of a microscopic optical or other light-based system 350 for pre-bond alignment, when two pads are spaced closer than the resolution limit of a system, this will appear as one feature in a captured image. No segmentation between pads will be visible in the captured optical image. Consequently, for a fiducial pattern 310 that is constructed of an array of active interconnect pads 304, if either the spacing between outer edges of the pads or the (pitch*duty cycle) product is smaller than the diffraction-limited resolution of the optical system being used, the image observed will appear to be an unbroken and solid (or continuous) shape or fiducial. This results in retaining the pattern recognition accuracy of a bonding overlay tool with the optical system and maintaining compatibility with current toolsets.

Referring to FIG. 4 for example, the fiducial region 308 on the array 302 is distinct from the array 302 due to the detectable fiducial pattern 310. The fiducial pattern 310 has pads 304 within the same group 312 or 314 that are separated by a group pitch P2 that may or may not be the same as an array pitch P1 between pads 304 in the array 302. The spacing Si between pads 304 in the same group 312 or 314 is less than the resolution limit. The spacing Si may be measured along the pitch lines. So arranged, the microscopic optical (or other light-basis such as NIR) system 350 will capture images of the fiducial pattern where the pads within the same group 312 or 314 cannot be distinguished. Consequentially, the groups 312 and 314 each show as a substantially (non-segmented) continuous shape 502 and 504, respectively, as shown on captured image 500 (FIG. 5) of the fiducial pattern 310. In this example, groups 312 are squares and group 314 is a cross, but many different shapes and patterns could be used instead. This may include concentric, ring-like, or hollow shapes, stripes, unsymmetrical shapes, and so forth. It should be noted that system 350 can be a light-based system with other types of light than just visible light, including, since it is being used for pre-bond pad alignment and takes direct images of a patterned side of a die or other electronic device, and most cannot be used for backside, post-bond misalignment when metallization may be present within the fiducial regions as described herein.

Visible (or detectable when NIR is used) segmentation spaces or lines 402, 406, and 408 between groups 312 and 314 of the fiducial pattern 310 are formed by setting a width S2 of the spaces 402, 406, and 408 that is greater than the resolution limit, and in turn, greater than the widths Si between pads in the same group. By one form, these widths Si and S2 are measured along or in the same dimension (such as in an X or Y dimension), but otherwise along a pitch line in this example. By one alternative form, regardless of pitch, the spacing widths between groups may be measured between two nearest points or side edges of two nearest pads of two groups. The segmentation lines or spaces 402, 406, and 408 have widths S2 between nearest pads 412 and 414 (or boundary pads of the groups 312 and 314), for example, that are at least the diffraction-limited resolution so that the resulting captured image will segment the groups. As a result, the maximum spacing Si forms solid groups 312 and 314 while minimum spacing S2 forms lines of the fiducial pattern 310 as shown on image 500 where segmentation lines 506 (FIG. 5) separate group shapes 502 and 504 from each other.

Another way to characterize the spacing is by pitch when the fiducial region 308 has rows and columns of pads with a uniform pitch, which may or may not continue the rows and columns of pads, and pitch, from the main array 302. Thus, a group pitch P2 within a single group is at most the diffraction-limited resolution (or S1) plus the width of a single pad 304. Likewise, the width of the space between two groups may be characterized as a fiducial pitch FP that is at least the diffraction-limited resolution (or S2) plus a width of a single pad 304. By one form then, the fiducial pitch FP is longer than the pitch P2 between pads 304 within a same group 312 or 314, and the fiducial pitch FP, based on the minimum width S2, at least partially generates the lines 402, 404, 406 of the fiducial pattern 310. By one example arrangement, the array 302 may be considered to include fiducial region 308 as part of the main array 302 that is distinct from a remainder 326 of the array 302. In this case, rows and columns of pads 304 are continued from the array 302 (where P1=P2) and into the fiducial region 308. In this example, the fiducial pitch FP is formed by at least part of a single column of pads 304 or part of a single row of pads 304 or both being omitted within the fiducial region 308 to form the lines 402, 406, and/or 408. In this example then, the pitch FP spans over at least or only a single missing row or column, although it could be more. In this case, the fiducial pitch FP is double the pitch P2 of the groups 312 and 314, and may be double the pitch P1 of the remainder 326 of the array 302.

By one approach, the fiducial pattern 310 may be separated from the array 302 by an L-shaped margin 404 free of pads 304, although many different shapes could be used instead such as straight (diagonal), generally curved, zig-zag or steps, and so forth, and that has a space width S2 at least as wide as the diffraction-limited resolution and may have a pitch across the margin that is the fiducial pitch FP between groups 312 and 314. When the fiducial pattern 310 is next to at least one of the corners of the array 302, the margin 404 may include a horizontal (parallel to the X-axis) line 406 and a vertical (parallel to the Y-axis) line 408. In this example, each group 312 also may be segmented from the cross group 314 by an L-shaped line 402 that has a width S2 and pitch of FP normal to the line 402.

It will be appreciated that the segmentation spaces or lines generated by using the spacing S2 may have many different configurations forming many different pad groups. By one form, the width S2 of the space between pads 412 and 414 is a uniform distance throughout the fiducial pattern 310, but in other examples, the spacing may vary along the same segmentation line or be different at different segmentation lines as long as the smallest spacing S2 is greater than the diffraction-limited resolution. With this arrangement, pre-bond pad alignment can be performed by using conductive pads that will be electrically active thereby increasing the pad density of the IC die, improve design flexibility and enable transistor functionality in previously inaccessible areas of the die.

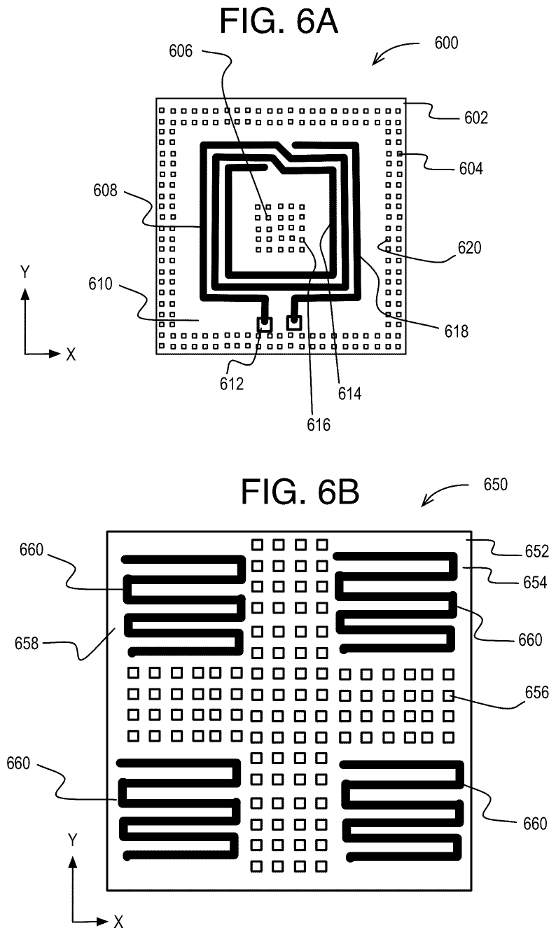

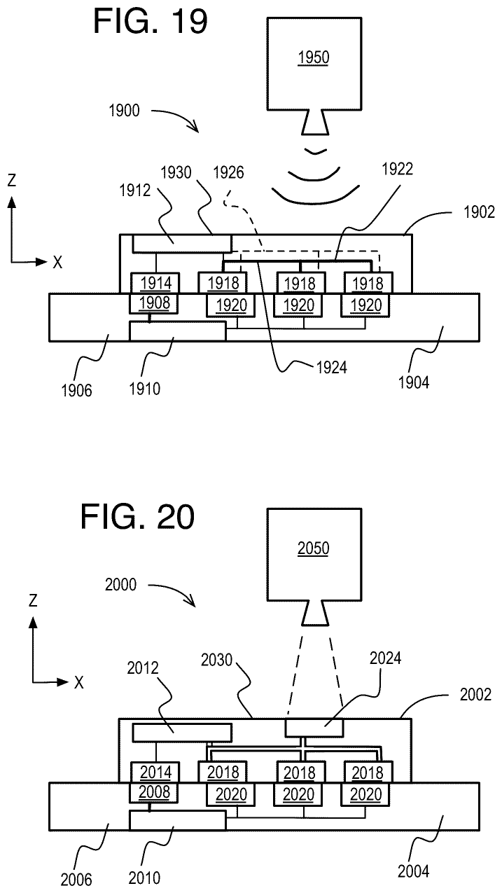

Referring to FIG. 6A as another alternative, an IC die 600 has a fiducial region 602 with a fiducial pattern 614 with spacing as described above except here space 610 between an outer frame group 604 of pads and a central or inner group 606 of pads may be much wider than the diffraction-limited resolution of the imaging device used to capture an image of the fiducial region 602, and may be sufficiently wide to hold a coiled antenna 608. The antenna 608 may form part of the fiducial pattern 614 as a fiducial or fiducial mark by providing a concentric or box-in-box fiducial that can be used for alignment. Specifically, an opposite fiducial region on an opposite electronic device may have a matching antenna or may have a space 610 to receive the antenna 608 from the fiducial region 602. Antenna interconnections 612 connect to traces, vias, or other metallization to couple the antenna 608 to circuitry of the IC die or electronic device. The antenna 608 may be formed of copper and may have other parameters as discussed below for wireless power transfer with package 1900 (FIG. 19).

As to the shape of the antenna 608, and by one example, the shortest distance between an inner-most loop 614 of the antenna 608 and the outer nearest or outer boundary pads 616 in the inner group 606 of pads should be at least the diffraction-limited resolution, and similarly the distance between an outer-most loop 618 of the antenna 608 and inner nearest or inner boundary pads 620 of the outer frame group 604 also may be at least as wide as the diffraction-limited resolution. In addition, the spacing between the loops of a single antenna coil should be less than the diffraction-limited resolution so that the coil will look solid as a fiducial in an image as described above with the groups of pads. Multiple different shapes, positions, and arrangements can be used for the antenna and fiducial pattern with the antenna as long as the diffraction-limit rule established here is followed. Thus, this includes coils or non-coil shapes. By one example form, the antenna may be 50 μm wide from inner to outer coil loop, and the space between the inner and outer pad groups 604 and 606 may be 100 μm wide. It also should be noted that even with metal coils, there still is no need for a KOZ under the coils due to the electrical probing described below. It also will be understood that inductors could be used in addition to, as, or instead of, antennas.

Referring to FIG. 6B as yet another alternative antenna layout, an IC die 650 has a fiducial region 652 with a fiducial pattern 654 that includes a pad array 656, here shaped as a cross, and where four corner groups spaces 658 each have a coiled antenna 660. Otherwise, the description is as mentioned above for IC die 600. It will be understood that many variations to this fiducial pattern may be used.

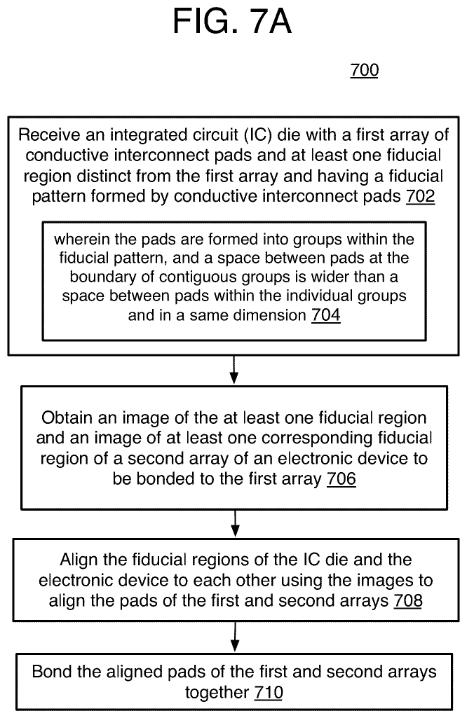

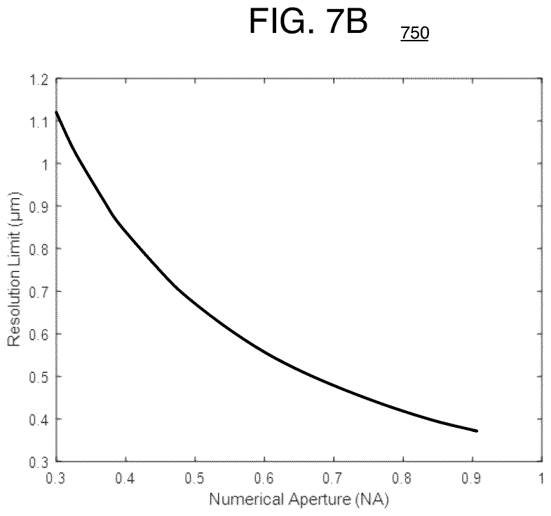

Referring to FIG. 7A, an example process 700 of manufacturing an electronic package is performed according to at least one of the implementations disclosed herein and describes an example pre-bond pad alignment using the arrangement of the fiducial region, and in turn fiducial pattern or fiducial marks, described above with FIGS. 3-6B. Process 700 includes operations 702 to 710 numbered evenly, and electronic systems, devices, IC dies, and/or image of FIGS. 3-6B may be referred to herein where appropriate.

Process 700 may include “receive an integrated circuit (IC) die with a first array of conductive interconnect pads and at least one fiducial region distinct from the first array and having a fiducial pattern formed by conductive interconnect pads,” 702, where the IC die may have one, two, three, or four fiducial regions, by one example. Two fiducial regions may be located on opposite corners or opposite sides or side portions of an array (or replace those opposite parts of the array, to detect small shifts in rotation, and by one form, on the order of micro-radians. The IC die also may include “wherein the pads are formed into groups within the fiducial pattern, and a space between pads at the boundary of contiguous groups is wider than a space between pads within the individual groups and in a same dimension” 704. This operation establishes the structure of the IC die to be obtained with the fiducial region arrangement already described above with FIGS. 3A-5, where the spaces between groups of pads of a fiducial pattern, which may be characterized by a fiducial pitch, are wider than the spaces between pads in the same group, which may be characterized by a first or group pitch. In this case, a pad alignment optical system can segment the different groups pads in a captured image while showing each group as a single continuous shape. Fiducial pitch, when based on a diffraction-limited resolution, in the fiducial region permits the segmenting of groups of pads, to form the fiducial pattern.

Referring to FIG. 7B for more detail, a graph 750 shows numerical aperture (NA) plotted versus resolution limit (Res). The data was obtained by using a central inspection wavelength of 550 nm (green light), which is typical for microscope optical systems. The graph 750 shows that the space between pads of contiguous groups (which is the resolution Res) depends on the numerical aperture of the optical system being used to image the fiducials, and precisely to determine the minimum space width that can be resolved to segment two pads by the optical system. So for example, for an optical system with an NA of 0.3, the diffraction-limited resolution Res from equation (1) above should be at least about 1.1 micrometers between the outer edges of two nearest pads of different groups so that the pads are distinguishable to the optical system. The optical system cannot resolve the nearest pads across a space between two groups if the spacing between the outer edges of the two pads is less than 1.1 micrometers. As such, assuming the pad width is the same as the distance of the gap between two pads, the minimum fiducial pitch that permits the optical system to resolve two segmented pads is 2×(1.1 μm)=2.2 μm pitch.

Here, it was assumed the pitch is the same as the pad spacing. To determine the fiducial pitch then, the resolution limit (or pad spacing) is equal to:

pad pitch*(1−duty cycle) (2)

where duty cycle=a percentage of the pitch that is occupied by a pad, e.g., if a pad is 2 μm wide, and the pad spacing is 2 μm wide, the duty cycle is (2/4)*100=50%=0.5, which can be checked by determining the pad spacing at 4*(1−0.5)=2 μm.

In other examples, as mentioned above, the pitch may be related to the number of parts of rows or columns of pads of the array being omitted from the fiducial region when the rows or columns or both are continued from the main array (or remainder of the array). By one form, a single row or column is omitted as shown on fiducial region 308 (FIGS. 3A and 4), but could be multiple parallel parts of consecutive rows or columns of pads being omitted from the fiducial region.

By another option, the range of spacing may be 1.1 μm to 400 nm wide for an NA of about 0.3 to 0.9 in green light. By another example, a larger example would be a 5× objective with green light which has an NA of 0.1. Now, the diffraction limit, and spacing, can be at most 3.3 μm between pads of a group, and equal to or more than that amount between the groups of pads.

The receipt of the IC die may be at a point when the fiducial region is ready to be captured in an image. This may be after the fiducial pattern is created on the die on wafer level during fabrication, then diced, and cleaned as well other treatment stages that may be performed. Thereafter, a bonder will lift the die and capture the images of the fiducials on both lifted die and the target wafer or die. As an alternative, the images of the fiducials could be captured in a number of different stages from before the IC die is diced from the wafer until the die is bonded to the target die, wafer or substrate.

Process 700 then may include “obtain an image of the at least one fiducial region and an image of at least one corresponding fiducial region of a second array of an electronic device to be bonded to the first array” 706. Here, the optical alignment tool may be an optical microscope or embedded optical imaging system on the bonder. This may include cameras using white light, RGB (Red/green/blue) light. However, even near infra-red (NIR) may be used, In either case, the cameras use light in order to modulate the NA of the optical system for pre-bond alignment, which permits modulating of the spacing of the fiducial pads to a most convenient spacing for the process. For example, if an NIR optical system (1 μm wavelength) is used for pre bond overlay, a limiting resolution becomes 6 μm, so that a pad spacing width less than 6 um pad can now be used to form a single shape and larger than 6 μm can be used to segment contiguous shapes. This technique permits use of electrically active fiducials on a much simpler, current process of 10 μm pitch (assuming pads are 4 um wide). Also, the microscope camera should have sufficient resolution and field of view (FOV) to capture the fiducial and image the segmented groups, but not enough resolution to segment the individual pads that make up the same group of pads.

Process 700 may include “align the fiducial regions of the IC die and the electronic device to each other using the images to align the pads of the first and second arrays” 708. This may include using vision algorithms to capture a center of the fiducial regions of the IC die as well as the target device where the die will be bonded to. The captured center coordinates can then be used to align the two devices to each other.

Process 700 may include “bond the aligned pads of the first and second arrays together” 710, where the IC die is placed on the other electronic device so that corresponding pads are now aligned. By one form, the HBI is performed where the pads on both facing arrays are initially recessed into their respective dielectric on both facing outer surfaces of the two devices. Thereafter, the assembly is heated for the pads to expand and then join together.

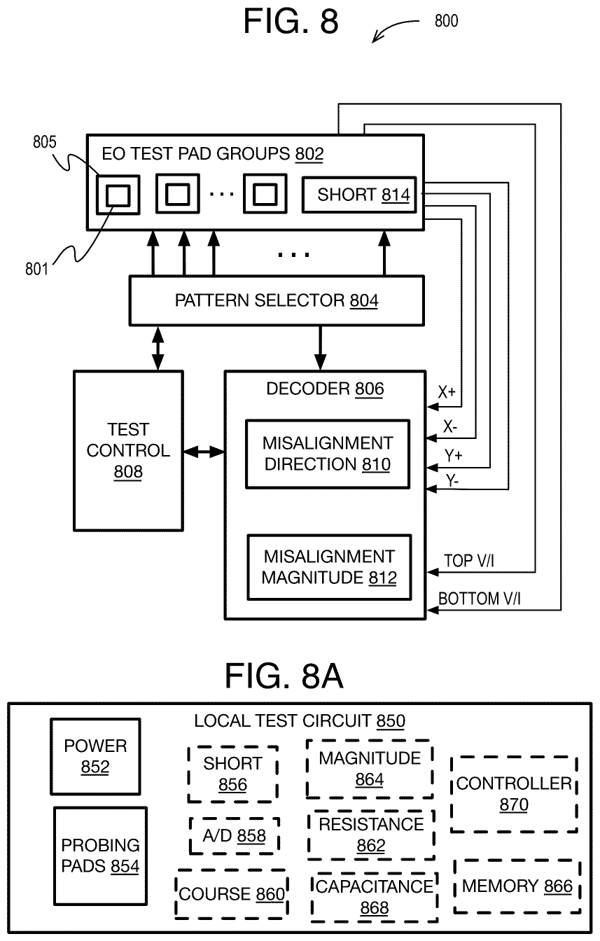

Referring to FIG. 8, in order to permit metallization to extend within and underneath a fiducial region and to avoid KOZs, a post-bond pad misalignment measurement system, device or circuits (post-bond device) 800 can be used instead of post-bond IR imaging, and for the example here, for D2 W or W2 W HBI bonding. The post-bond device 800 may have an electrical overlay (EO) ETO unit 802 that has a set of electrical testing overlays 801 each with multiple pads to be activated.

By one form, a local test circuit 805 may be over, near, or local to each ETO 801. The term local here refers to near or in the vicinity of the pads being activated, or in other words, being on-chip and on the same array or same fiducial region of an IC die as the pads being activated. Thus, a local test circuit 805 may be on each opposite side (top and bottom) of the ETO 801 including at least one local test circuit 805 over each one of the fiducial regions bonded together with the bonding of the arrays of the IC die and other electronic device. Otherwise, two or more of the ETOs 801 may share the same local test circuit 805. Specifically, while providing one local test circuit 805 for each ETO 801 permits measurements from the groups in parallel, it is possible to have a few neighboring ETOs share the local test groups. This may depend on a complexity and location of local test circuits 805.

The local test circuits 805 may have a number of different arrangements and functions. By one option, the local test circuits 805 at least receives power from external power supplies to activate pads of one or more of the ETOs 801, and then may probe the activated pads to read electrical levels (for example voltage and current). When these are the only misalignment measuring functions performed by the local test circuit 805, the local test circuits 805 are described as providing electrical pad signals (or levels) for coarse measurements. In this case, the local test circuit is simple and may not be shared since these circuits are small such that duplication is relatively not very costly (in area, power consumption, and/or financial cost).

In this case, the further misalignment direction and magnitude computations may be performed at circuits or units separate from the local test circuits 805. For example in this case, the EO ETO unit 802 also may have a short (or loop or closed circuit or short circuit) unit 814 to detect a closed or short circuit when pads of the ETOs are in contact, which may include resistance calculations as described in detail below, and then to transmit binary or analog misalignment direction signals to a decoder 806 to finalize the misalignment direction and output an indicator of the direction. The post-bond system 800 also may have a pattern selector 804 to select patterns for signal transmission and switch from one to the other as the ETOs are being analyzed. The decoder 806 may have a misalignment direction unit 810 to determine a misalignment direction upon receiving the misalignment direction signals from the short unit 814, and a misalignment magnitude unit 812 that uses the misalignment direction signals as well as electrical levels from the local test circuits to determine a misalignment magnitude or distance. In this case, a test control unit or controller 808 also may be provided to operate the units of the system 800.

By one approach, the decoder 806, pattern selector 804, and controller 808 are external to a package being tested, and may attach to I/O pads on a wafer with one of the bonded arrays and described below in detail. Thus, an alternative method could be to have all functions performed externally, where no need exists for integration of local test circuits. IN this case, external lab equipment may be used instead to probe the pads using custom probes or probing cards around the IC die that are electrically coupled to power and I/O pads on a wafer for example, and in this case, this routing may be through frame pads.

By yet another approach, some or all of these functions may be provided on a unit or circuit separate from the local test circuits 805 but still on board the IC die and/or wafer providing the bonded arrays. Such unit may be in place of the short unit 814 and may be a digital controller in this case that can control all of the local test circuits 805 and transmits all output regarding the misalignment of the ETOs 801. The input/output may be provided though a probed digital acquisition and control system.

Referring to FIG. 8A, as yet another alternative, a local test circuit 850 may have circuitry to perform much or all of the functions mentioned above being performed by post-bond device 800. Specifically, the local test circuit 850 may obtain power, activate and probe an ETO 801, determine the misalignment direction, determine the misalignment magnitude, and output the misalignment direction and magnitude. To accomplish this, the local test circuit 850 may have a power unit 852 to receive and store power, a pads probing unit that activates the ETO and reads the electrical levels of the pads, and a short (or short circuit) unit 856 that measures pad contact resistance, and compares the measured resistance to a stored value in an on-board memory 866 to determine if pads are in contact and thereby quantify misalignment. The short unit 856 may provide analog signals or digital signals with use of an A/D unit 858 to indicate the misalignment direction to a controller 870 that outputs the direction data.

As to the misalignment magnitude, the local test circuit 850 may have a coarse unit 860 that determines a coarse or range of magnitudes using the geometry of the ETO and as explained below. The magnitude range may be provided to the controller 870 for outputting. In addition, or instead, for precise resistance measurement, and in turn precise misalignment magnitude, the local test circuit 850 may have a resistance unit 862 and a magnitude unit 864. By one option, the resistance unit 862 computes a measured contact resistance of the pads in contact. A reference resistance is then determined by using the known pad surface area or resistance of an on-chip reference resistor. A magnitude unit 864 then uses the resistances to use a look-up table in the memory 866 to indicate a misalignment magnitude (or distance). Optionally, a capacitance unit 868 may provide a capacitance-based contact or overlap surface area as well to find a misalignment amount in a look-up table. The two misalignment magnitudes can be combined such as by averaging, or looking up both the capacitance and resistance based contact surface areas. The resulting magnitude is then communicated externally.

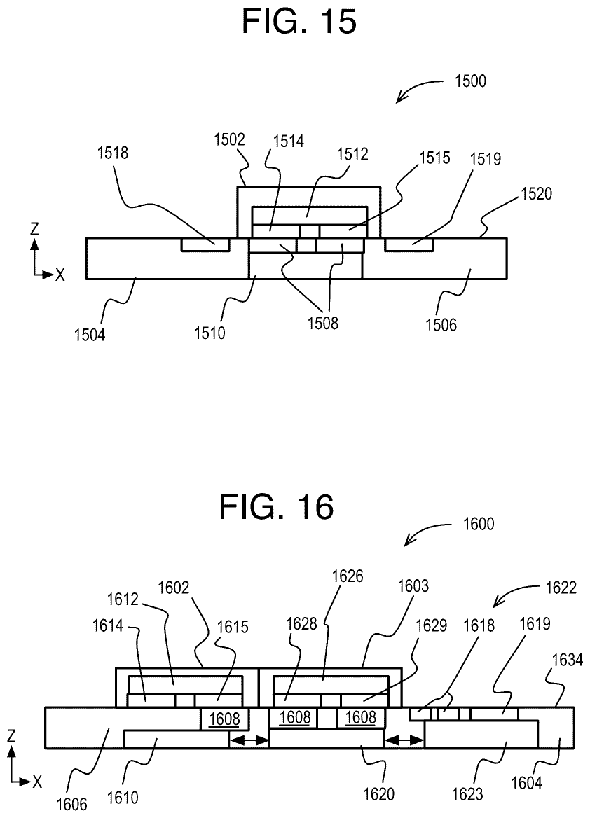

Due to the complexity of local test circuit 850 and similar local test circuits that are used to compute precision resistance and capacitance measurements to determine accurate misalignment distance, these circuits may be too expensive to be duplicated and one local test circuit 805 for multiple ETOs 801 should be used instead. Further details of the configurations of the ETOs and local test circuits are described in FIGS. 15-21. The operations mentioned here are described in detail below with FIG. 14.

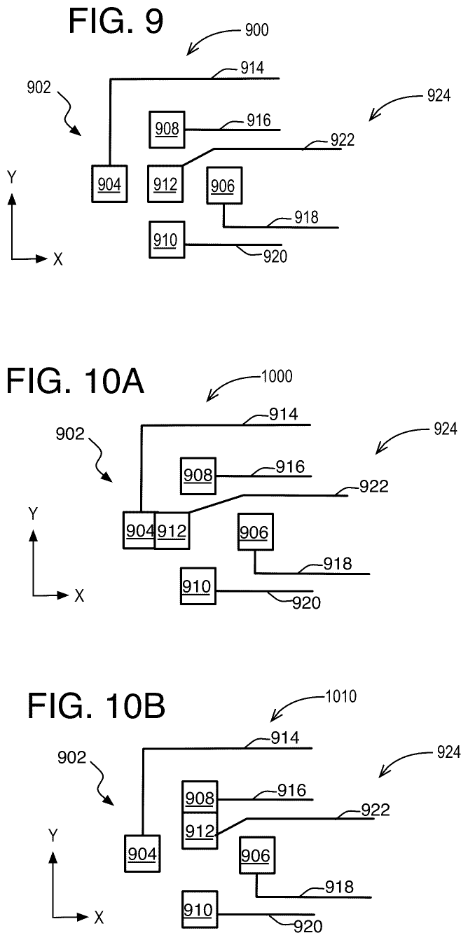

Referring to FIG. 9 for details of the ETOs, a set of multiple ETOs 900, which is the same or similar to the ETOs 801, can be electrically activated and probed to determine if any of the pads on two different but bonded arrays are touching to determine a misalignment direction. In one alternative, the ETO 900 also can be used to determine the amount or distance of the misalignment. To detect the misalignment direction and magnitude post-bond, a single alignment monitoring pad 912, after bonding, may be co-planar to pattern pads 904, 906, 908, and 910 of an ETO pattern 902 around the monitoring pad 912 and on another array to be bonded to the array of the IC die with the monitoring pad 912. Initially before bonding, the monitoring pad 912 may have been slightly vertically offset (in a Z-dimension or in and out of the paper on FIG. 9) from the pattern pads of the other array, although here too, the opposite pads, from a side view, may have been largely co-planar as well. Also, the monitoring pad 912 is horizontally aligned in X-Y dimensions, with the electrical ETO pattern 902 on the other array on an electronic device such as a die on a wafer. The ETO pattern 902 may have multiple pattern pads, here being the four pads 904, 906, 908, and 910, although more or less pattern pads could be used. The monitoring pad 912 is amid or centered horizontally within the pad group pattern 902 in a plan view (X-Y view) as shown on FIG. 9 so that initially the monitoring pad 912 does not touch any of the pattern pads 904, 906, 908, and 910. The testing pads 904, 906, 908, 910, and 912 may be part of circuitry 924 and respectively may include electrical transmission conduits (or just lines) 914 to 922 numbered evenly.

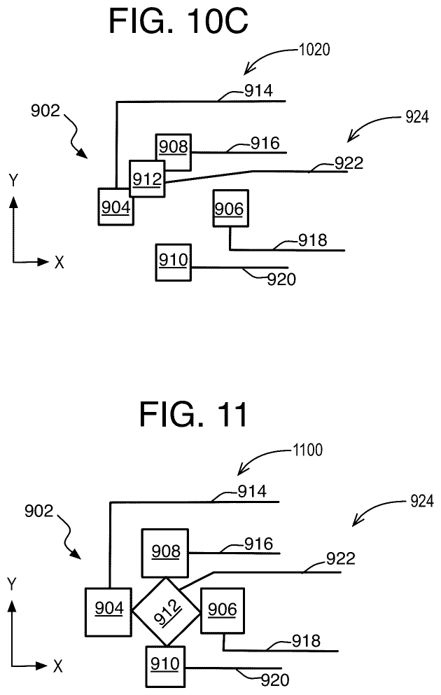

Referring to FIGS. 10A-11, setups 1000, 1010, 1020, and 1100 show the arrangement of the ETO 900 in various misalignments after bonding. Setup 1000 (FIG. 10A) shows misalignment in the X dimension (X−) where monitoring pad 912 contacts the pad 904 of the ETO pattern 902. Setup 1010 (FIG. 10B) shows misalignment in the Y dimension (Y+) where monitoring pad 912 contacts the pad 908 of the ETO pattern 902. The setup 1020 (FIG. 10C) shows bidirectional misalignment where the monitoring pad 912 is shifted diagonally and into contact with both pads 904 and 908 (X−, Y+ direction). The setup 1100 (FIG. 11) shows rotation misalignment where the monitoring pad 912 rotates into contact with pads 904, 906, 908, and 910. This, however, detects very gross rotation. To measure rotation in a much more precise manner, the same testing arrays are probed at two opposite corners of a die as described below. The post-bond device 800 activates these pads and receives signals from the pads that indicate which of the pads are in contact in at least these four possible misalignment setups as explained below.

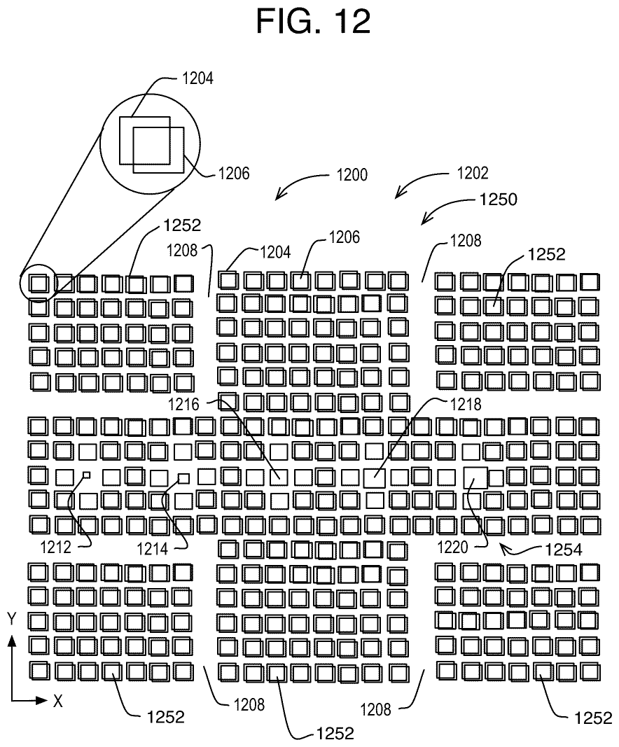

Referring to FIG. 12, an electronic package 1201 has two bonded fiducial regions 1200 and 1202 at least generally coplanar to two bonded arrays (such as on FIG. 3A or 4) where the IC die described herein may have fiducial region 1200 and the other electronic device to be bonded to the IC die may have the other fiducial region 1202, or vice versa. The fiducial regions 1200 and 1202 respectively have bonded pads 1204 and 1206 with a misalignment as shown in the close-up circle. As described above, the fiducial regions 1200 and 1202 have a matching, mirroring, fiducial pattern 1250 with spaces 1208 between pad groups 1252 that are at least a width of the diffraction-limited resolution while the pads 1204 and 1206 within the same group 1252 are separated by smaller spaces less than the diffraction limited resolution. In this example, a set 1254 of five nested ETOs 1212, 1214, 1216, 1218, and 1220 are spaced or interspersed within the fiducial patterns 1200 and 1202. The set 1254 of ETOs are formed of the electrically active pads 1204 and 1206 of the fiducial region that can be probed after bonding to calculate misalignment. By one form, the ETOs 1212, 1214, 1216, 1218, and 1220 are limited to the fiducial regions 1200 and 1202 as shown to separate the functionalities of the main active array (or active portion of the die) versus the alignment testing in the fiducial region. In one further example, an antenna may be used to power the ETOs as described below, and the relatively large area of the fiducial region occupied by an antenna rather than active pads does not severely affect the pad density of the active portion of the IC die.

Alternatively, however, all or part of the set 1254 of the ETOs could be located anywhere desired in the main array (or active portion) of the IC die and other electronic device. Since the circuit for the set 1254 can take up active area (even though quite small), it would be easier to compartmentalize the ETOs at the edges of the array with minimal effect to the active portion in the IC die and other electronic device. This could be used when the parasitic resistance and/or capacitance of the circuit is low. The antenna implementation may provide a wireless power and radio frequency ID (RFID) approach basically permitting power up and communication with the post-bond system circuit without physically probing the circuit so that the testing could be performed at the center, edges, or anywhere else on the IC die and other electronic device if such implementation overcomes the pad density issues mentioned above.

Returning to the example of the fiducial regions 1200 and 1202, while five electrical ETOs 1212, 1214, 1216, 1218, and 1220 are shown in a periodic array. The number of ETOs may be selected to provide an adequate number of monitoring pad size variations as discussed below and may be limited by lithography parameters. By one form, 18 or 20 ETOs may be provided, and by another form, at least five such groups may be provided, and by another example at least 15 groups may be provided. Also, while the ETOs are shown on the same row of pads in the fiducial region, this is done for efficiency during manufacture and for ease of probing physically so they can be tested in parallel as the circuits will be co-located. Otherwise, the ETOs may be spread around the fiducial regions 1200 and 1202 (or main arrays) in a wider area.

Also, in order to provide a more uniform coplanar surface at the bonding interface surface of the pads 1204 and 1206 (before bonding), the alignment monitoring pads may have an opposite floating pad that is not connected to any circuits. The floating pad should not affect the contact sensing through the multiple probed pads of the ETO pattern. The pads of the ETO pattern also each could have their own opposite floating pad as long as correct alignment and misalignment measurement is not affected. Otherwise, the spaces above (or below) the probed electrically active pads in the ETOs are simply not patterned with pads like 1204 and 1206 and the bonding interface would thus have dielectric on one side and a pad on the other.

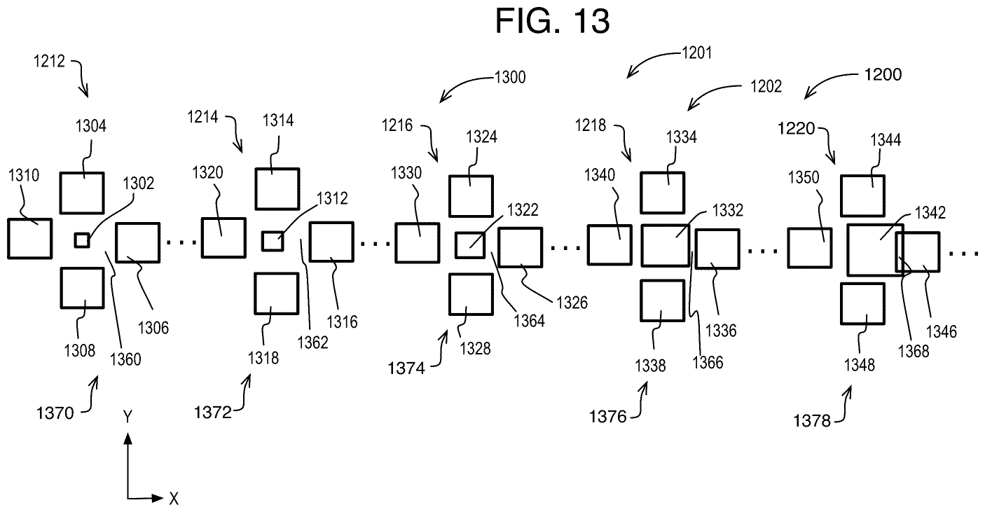

Referring to FIG. 13, the electronic package 1201 may have the set 1254 of ETOs 1212, 1214, 1216, 1218, and 1220 spaced in a periodic array 1300. Each of the ETOs 1212, 1214, 1216, 1218, and 1220 respectively have a monitoring pad 1302, 1312, 1322, 1332, and 1342 located in either the fiducial region 1200 of the IC die or the electronic device, and respectively in or near the center of the pattern pads of the ETO patterns 1370, 1372, 1374, 1376, and 1378 in the opposite array (either the other of the IC die array or the electronic device) and in X-Y plan view. The pattern pads around each monitoring pad are numbered evenly and consecutively after its monitoring pad. Thus, monitoring pad 1302 is amid pads 1304 to 1310, and so forth. The monitoring pads are shown here in a linear misalignment (toward the right in the X dimension) as indicated by the overlapping pads 1342 and 1346.

By one form, the monitoring pads 1302, 1312, 1322, 1332, and 1342 each have a different size to provide an increasingly fine overlay resolution. The different sizes of the monitoring pads are used to obtain a quantitative granularity for bonding overlay measurements by forming a periodic array 1300 of these features where the monitoring pads 1302, 1312, 1322, 1332, and 1342 each become larger within the confines of the corresponding ETO pattern 1370, 1372, 1374, 1376, and 1378. Thus, at least initially, the largest monitoring pad 1342 is sized so that it does not touch the pads 1344, 1346, 1348, and 1350 of its ETO pattern 1378. This progressively decreases the horizontal (X-Y dimension) width of the offset between the outer edge of the monitoring pad and the outer edges of the pads in the corresponding ETO pattern. This can be referred to as reducing the manufacturing alignment tolerance of the ETOs as the monitoring pad becomes larger since the misalignment distance that can be detected by electrical probing is smaller as the monitoring pad becomes larger. Thus, it is easiest to detect contact between the pads with the largest monitoring pad. By knowing the size of the monitoring pad, and the nominal (by design) horizontal (or Y and/or X dimension) distance or offset between the monitoring pad and the ETO pattern pads, a quantitative value (or magnitude or distance) for overlay misalignment can be found by using data from a misalignment direction determination described below. The misalignment magnitude can be determined as a coarse range or a precise amount also as described below.

By one form, the ETOs should be within the same group of pads within a fiducial pattern (or in the main array) and have a uniform smaller horizontal (X-Y dimension) spacing between pads and pitch than that of the pads separating groups with the fiducial pitch. Thus, the granularity or size of the increase in width of the monitoring pads from ETO to ETO may be increased uniformly and over a number of size steps or variations in width depending on the factors mentioned above. This may be determined by experimenting as well. For example, if 8 steps are found to provide good results, and the pads are square with a 2.0 μm spacing, each monitoring pad may increase progressively by (2.0 μm/8)=0.25 μm until a maximum of just less than the spacing itself i.e. 2 μm. The size steps may be varied or have many different values.

By alternative forms, the monitoring pad in the center of the ETO may have different shapes, such as being rectangular, so that the offset between a monitoring pad and the pads of the ETO pattern is different for both the X and Y dimensions. This may be used when more granularity is needed in detecting misalignment in one direction versus the other.

Referring to FIG. 14A, a process 1400 of performing post-bond misalignment measurement may be performed according to at least one of the implementations disclosed herein. Process 1400 includes operations 1402 to 1414, numbered evenly, and electronic systems, devices, and/or IC dies of any of FIGS. 3A-13 may be referred to herein where appropriate.

Process 1400 provides the flow for deciding among which of alternative operations should be used to determine misalignment magnitude. Process 1450 (FIG. 14B) below provides the detailed operations to compute misalignment direction and misalignment magnitude.

Process 1400 may include “for coarse measurement, determine which ETO has a short in X or Y dimension” 1402. This may involve determining if a resistance at any of the pattern pads is non-zero, and by one form, also above a threshold. Four binary or analog signals can be generated, one for each pattern pad for a four pad testing group pad pattern, although more or less pad patterns could be used.

A decision then may be made: “Further precision desired?” Particularly, coarse measurement may be sufficient for initial development stages where precision may be needed for high volume manufacture (HVM) stages. Also, precision may be activated at less than all or only a few reticles and not across the entire wafer. This decision may simply be manual and set in the system to perform the precision or coarse operation. Otherwise, an automatic decision could be implemented by code or circuitry that detects a coarse misalignment below a certain threshold. This determination may be coded or in hardware or firmware on the local test circuits, on-chip or frame controller, post-bond device 800, or any other external pad misalignment system.

When only a coarse misalignment measurement is desired, a misalignment range may be determined by using the known nominal (by design) width of the monitoring pad and the nominal spacing between the outer pattern pads.

Process 1400 may include “report coarse misalignment (spacing—pad width)” 1404, where the four direction signals (or just a direction indicator that analyzes the fours signals) as well as the misalignment range is output from the misalignment measurement system.

Otherwise, when the decision “Further precision desired?” is yes, then process 1400 may include “precision measurements for resistance” 1406, which may include “enable resistance measure circuits to quantify resistance of overlap area between top and bottom pads” 1408, or in other words, for the monitoring pad and the surrounding pattern pads of an ETO, whichever is on top by one example. This may include computing a contact resistance, and then a reference resistance that can then be used to determine misalignment. The reference resistance can be determined by either using a maximum resistance based on pad size or a resistance compared to an on-chip resistor, followed by misalignment calculation by comparing against a look-up table.

Process 1400 may include “report measured values to controller” 1410, where the controller may output the magnitude and direction values external to whichever device (local test circuit, frame circuit, or external alignment system) computed the misalignment magnitude and for further analysis and adjustments to the manufacturing alignment tools.

Another inquiry of “capacitive measure needed?”, and capacitance may be computed in addition to the resistance based misalignment when further precision is needed or when an accurate resistance measurement may not be possible, e.g., if the resistance value of the post-bonded pads is extremely small. The capacitance operation may be set manually to always occur, or may be set to automatically be computed under the circumstances mentioned. This determination may be coded or in hardware or firmware on the local test circuits, on-chip or frame controller, post-bond device 800, or any other external pad misalignment system.

When capacitance also is determined, process 1400 may include “enable capacitive measure circuits to quantify capacitive top and bottom pads” 1412. For this operation, capacitance between the monitoring pad and two pattern pads not in contact, as well as reference capacitance, may be used as described below to determine a capacitance-based misalignment magnitude. The capacitances than may be either combined with the resistance based misalignment magnitude or used to confirm or enhance the resistance-based magnitude (or vice-versa).

Process 1400 may include “report measured values to controller” 1414, which is the same as operation 1410.

Referring to FIG. 14B, a process 1450 of performing post-bond misalignment measurement may be performed according to at least one of the implementations disclosed herein. Process 1400 includes operations 1452 to 1478, generally numbered evenly, and electronic systems, devices, and/or IC dies of any of FIGS. 8-13 may be referred to herein where appropriate.

Process 1450 may include “electrically activate ETOs” 1452, and where “each monitoring pad having a different size” 1454 as already described above to form various offsets between pads for various tolerance levels. For this operation, probing may be performed in a number of different ways. By one example, the pattern selector 804, if provided, (FIG. 8), selects an ETO to be tested, and may select the next group when the probing or analysis of the previous group is complete. Otherwise, the local test circuits may each operate separately and obtain (or provide) probe data in parallel. By one example form, the pads can be probed in parallel across multiple ETOs. Thus, for example, all the X+ pads may be probed simultaneously, then the X− pads, and so forth. In this way, the misalignment system or device can flag which ETO has the first non-zero signal greater than some threshold (digital or analog), and the misalignment for that ETO then may be a baseline misalignment in that dimension. Otherwise, ETOs can be probed in any way including individually, simultaneously in parallel, or in groups and found to be efficient or accurate.

In operation, a local test circuit may be electrically powered up by using power peripheral or other types of pads as described below, and then may input an injection signal to the monitoring pad of the ETO. The injection signal may be a reference current of a pre-specified amplitude.

Process 1450 then may include “determine electrical voltage and current levels of each pad” 1456. Here, a short (circuit or closed circuit) unit may receive signals from local test circuits at the electronic device (or wafer) electrically coupled to the pattern pads of the ETO of the wafer ETO (or pattern or bottom ETO). The pattern local test circuit may provide voltage and current levels of each of the pads of the ETO pattern to the short unit 814. The electrical levels of the monitoring or top pad also may be obtained when such circuitry exists. The short unit may be integrated on the local test circuit, frame, or other area of the IC die, or may be external on other electronic device, misalignment system equipment, and so forth as mentioned above.

Process 1460 then may include “determine a misalignment direction of one or more monitoring pads” 1458, and for this operation, process 1400 may include “determine which pattern pads of an ETO pattern are in contact with a monitoring pad” 1460. Here, a rough contact resistance may be determined using the electrical levels (e.g., interconnection or rough contact resistance R=I/V). The electrical levels of each pattern pad in the ETO is determined. When R is high (above a threshold which may be at MOhm amount or above, no contact exists between a monitoring pad and a pattern pad. Thus, when the resistance is closer to zero, such as milliohms and below, or otherwise below the threshold, this indicates strong or relatively large amount of contact. The threshold is determined by experimentation. Other alternative methods could be used as well.

When the ETO pads are properly aligned, this should indicate pads in the main array and fiducial region overlay are properly aligned. In this case, the short unit generates analog or digital signals, one for each pattern pad, that indicates no contact between pads. However, in cases with misalignment between pads sufficient to cause resistance below the threshold, the short unit may generate analog or digital contact signals for each resistance level of the pads in contact.

Process 1450 may include “provide misalignment direction indicators” 1462. This operation may involve transmitting signals from the local test circuits (or EO test pad groups unit 802) to indicate the direction of the misalignment when one exists and when external misalignment units perform further misalignment processing. Otherwise, the direction signals may be provided to a misalignment resistance or magnitude unit on a local test circuit for further processing. By one example, when the ETO pattern has four pads with one on each side of the square monitoring pad, a binary signal may be formed to indicate contact between a pattern pad and the monitoring pad. By one form, when contact exists, then a 1 is transmitted, and when no contact exists, then a 0 is transmitted. The signals may be provided for each of the four pads and may be labeled by dimension: X−, X+, Y−, and Y+, and the direction may be indicated by the binary signals as on the following possible random example Table I (although many different configurations can be used):

TABLE 1
MISALIGNMENT DIRECTION

| FIGURE | X+ Y+ X− Y− | MISALIGNMENT | DIRECTION |
|---|---|---|---|
| 9 | 0000 | None | — |
| 13 | 0001 | linear | X+ |
| 10A | 0010 | linear | X− |
| 10B | 0100 | linear | Y+ |
| | 1000 | linear | Y− |
| | 1100 | bidirectional | X−, Y− |
| 10C | 0110 | bidirectional | X−, Y+ |
| | 0011 | bidirectional | X+, Y+ |
| | 1001 | bidirectional | X+, Y− |
| 11 | 1111 | rotational | — |

Some of the figures show example misalignment arrangements as indicated by the figure number on Table 1. By one form, the operations to obtain the four binary signals are repeated for each ETO. The misalignment direction unit 810 at the decoder 806 may receive the four binary signals and record, in registers or memory, which pads have a ‘1’ or otherwise indicate the pad is to be used for determining the misalignment magnitude for the ETO.

It will be appreciated that more than four pads could be used for greater accuracy such as 8 pads surrounding a monitoring pad including diagonal neighbor pads. It also will be appreciated that analog signals in the form of different amplitude, phase, or frequency levels that encode measured information may be provided instead of binary data digits.

Switching now to misalignment magnitude, process 1450 then may include “determine a misalignment distance of a monitoring pad” 1464. As mentioned with process 1400, either a coarse or more precise misalignment magnitude or both may be computed, Process 1450 assumes both coarse and precise (or fine) magnitudes are desired and are described below.

Process 1450 may include “perform coarse measurement” 1466. Here, the measurement may be performed by the coarse unit of a local or frame test circuit or the misalignment magnitude unit of an external system or device.

For example, using the set of test pad groups of FIG. 13, say no contact (resistance above a threshold) is detected at an X+ pattern pad of a third ETO 1216 (where initial offset=A between top monitoring and bottom pattern pads) but the fourth ETO 1218 with a larger monitoring pad (where initial offset=B between top monitoring pad and bottom pattern pads, and where A>B) has contact. In this case, say the misalignment direction output is (0 0 0 1). In this case, where offset A>offset B, the misalignment is in a range from:

B≤misalignment<A (3)

All of the ETOs may be probed to find both an X dimension misalignment and a Y dimensions misalignment. When a bidirectional misalignment is indicated, the misalignment range can be determined by combining X and Y components. Thus, for the four pattern pads used in the example herein, once all four X and Y directions are considered, the bidirectional total overlay metric can be summarized with the Pythagorean Theorem as sqrt(X_mis²+Y_mis²). A gross or coarse rotational angle may be determined by determining the magnitude on all four pattern pads when it occurs, and then using a look-up table for rotation. Otherwise, a more precise rotational misalignment may be determined by measuring X and Y misalignment vectors on two fiducial regions on two opposite corners (or sides) of an array on a die, and then finding the angle between them, which is described below as well.

Process 1450 may include “determine contact and reference resistances of pads in contact” 1468. The contact resistance of two shorted pads (or the two pads in contact) may be provided by:

R=ρ*th/SA (4)

where R=R_{meas.}, th is the thickness of two shorted pads in contact, SA is shorting surface area, and ρ is the known resistivity of the material (such as copper). The thickness of shorted pads may be within nanometer accuracy through monitoring of a plating process (e.g., 1 um per pad, 2 um per pad, 3 um per pad etc.). The shorting surface area is obtained by solving equation (4).

The contact resistance may be an analog value that can be transformed to a digital word, such as a binary word, that is sent to a controller. The digital word may be in a format of 4, 8 or 12 bits. The controller may use the word directly to look-up misalignment magnitude in a look-up table in a memory.

By another option, the analog contact resistance value may be used directly to compare to an analog reference resistance in the following operations. Particularly, the resistance-based operation 1468 includes determining a reference resistance. Circuits to quantify resistance can be based on either a look up table for determining the reference resistance or alternatively to the reading of a reference resistor on chip. Specifically, if the full area of the bottom pattern pad and top monitoring pad in contact are shorted, this will provide a minimum resistance R_refₘᵢₙ. The maximum shorting area is A_max=a*a if square pads are used with an edge length a. The reference resist is then listed on a look-up table depending on the maximum shorting area.

Alternatively, a dedicated resistor on-chip can play the role of R_ref above and the circuit can always measure “against the on-chip resistor” for greater accuracy and/or precision. This is possible because the output of the measurement circuit (e.g. differential amplifier) would be proportional to R_meas/R_ref, and R_ref can be obtained by reading (or computing) the resistance at the reference resistor when performing the probing of the ETO. Alternatively, the measurement circuit performs the measurement first at the pads and then over the reference resistor. Both values are saved and compared.

Once the reference resistance is obtained, process 1400 may include “determine the misalignment magnitudes using the contact and reference resistances” 1470. A ratio may first be used to compute the ratio of the areas:

R_meas/R_ref=A_calc/A_max (5)

where A_max and R_meas are inversely proportional. Once the overlap is determined, the overlaps may be listed on, or interpolated on, a look-up table. A look-up table, or separate part thereof, may be provided per testing group pattern (or monitoring pad size) and per each possible main X and Y misalignment direction. The look-up table may be arranged to provide relatively precise values, whether listed on the table or to be interpolated, or may provide a range of magnitude values.

By yet another alternative, an equation may be used to compute the misalignment rather than using the look-up table to convert contact surface area to misalignment magnitude. The equation may be used when a direct resistance versus misalignment look-up table exists (e.g., based on theory or other experiments). The equation here may be:

Misalignment M=k*R_meas/R_ref (6)

where k may be a customized proportionality factor determined by heuristics, R_meas is the contact resistance, and R_ref is the reference resistance as described above.

By another alternative, process 1450 may include “compute contact and reference capacitances of pads in contact” 1469. Here, a capacitive circuit can be used to determine differences in capacitance between neighboring pads (with either a single capacitance or differential capacitance) at the ETO. This capacitive monitoring, along with the resistance monitoring, can further allow characterization and/or quantification of the misalignment of the assembly. Specifically, since the monitoring pad should be centered between pattern pads of the ETO, a capacitance circuit can detect and measure a shift in the position of the monitoring pad relative to the pattern pads by determining two capacitances each being between the monitoring pad and a pattern pad on opposite sides of the monitoring pad. The capacitances can be used to determine a separate capacitance-based misalignment magnitude by using some similar operations to that used to determine the resistance-based misalignment magnitude. Thus, both capacitive and resistive readout is possible and can be combined or used to confirm the accuracy of one or the other magnitude. The capacitance measurement will be used to compare against a reference capacitance (as in the case of resistance measurement) and the ratio between measured vs. reference values will be translated to a misalignment value, using a look-up table or equation as with operation 1470 for resistance.

Referring to FIG. 14C, a package 1480 may be used to explain the capacitance misalignment computations. The package 1480 may have an IC die 1482 bonded to an IC die on a wafer 1484 as described with other packages above. Here, the wafer 1484 may have interface or array pads (or fiducial pads) 1486, 1488, 1490, and 1492. The IC die 1482 may have interface or array (or fiducial) pads 1498 and 1496. An ETO 1498 includes the top or monitoring pad 1494 and pattern or bottom pads 1486 and 1488. The pattern pads 1486 and 1488 may be coupled to an a local test circuit 1495 that provides, or is coupled to, parasitic capacitor Cref1 on a line between pattern pads 1486 and 1488, and a parasitic capacitor Cref2 on a line between pads 1488 and 1490. Two parasitic capacitors C1 and C2 are formed by the opposite sides of the monitoring pad 1494 and the monitoring pad to the two opposite pattern pads 1486 and 1488. Otherwise, the IC die 1482 and wafer 1484 may include dielectric material that surrounds, supports, and/or covers the metallization just mentioned.

Wirth this arrangement, circuits to quantify capacitance can be based on either a look up table or using an on-chip reference capacitor Cref2. Capacitance between two neighbor pads, such as a monitoring pad and pattern pad of an ETO, that are not shorted is calculated as:

C_meas=e_0*Ao/dbp (7)

where e_0 is permittivity, Ao is area of overlap, and dbp is distance between plates. Since the area of overlap is known as the sidewall area of the pads (pad thickness multiplied by pad width), the dbp is a measure of misalignment that can be determined by either solving (7) after an absolute capacitance measurement to determine C_meas. Furthermore, the C_meas can be directly compared to a look up table that has misalignment magnitudes for pre-calculated capacitances. For increased precision or accuracy the measurement should rely on capacitive ratios C_meas/C_ref where C_ref can be either a capacitance C_ref₁ of an on-chip capacitor Cref1 or a capacitance C_ref₂ of a capacitor Cref2 measured between two pads 1490 and 1488 of the same IC die 1482 (and which is known to be non-shorted (open) and where the pads 1486, 1488, and 1494 are at a pre-defined pitch as shown on FIG. 14C. The ratio then can be used to determine an accurate capacitance value C_meas which in turn will be compared again to a look up table.

A few options exist to connect the local test circuit to the IC die pads and the wafer pads. Since no connection exists between the monitoring pad and the pattern pads, instead a capacitive measurement is performed that measures capacitors C1 and C2. This may be used when the local test circuit only has access to the pattern pads. In this case, a capacitance ratio may be used of a ETO pattern capacitor Cref1 (C_ref₁+C_misalign) over capacitor Cref2 (C_ref₂). C_misalign is the series connection of measured capacitors C1 and C2. C_misalign is then used to quantify misalignment.

Alternatively, the backside 1499 of the IC die 1482 may have a contact 1497 coupled along a path to the monitoring pad 1494 as well. This extra contact 1497 can provide the capability to further understand the capacitance of the left capacitor C1 versus right capacitor C2.

Note that the capacitance misalignment computation ignores fringing capacitance even though the pads 1498, 1492 of the IC die 1482 and the pads 1486, 1488, 1490 of the wafer 1484 are not on the exact same vertical (Z dimension) level. Thus, the area of overlap does not necessarily equate to pad thickness x pad width. When the capacitance is not sufficiently accurate, a more accurate capacitance expression can be created.

When capacitance is also being used, then the resistance and capacitance misalignments may be combined, such as by averaging, to determine a final misalignment magnitude. Otherwise, both misalignments may be used to confirm the other misalignment. Thus, if the capacitance misalignment is within a certain percentage of the resistance misalignment, then the resistance misalignment (or largest, or smallest of the two) may be used.

Process 1400 may include “compute the direction-specific misalignment distances” 1472, and specifically, depending on the misalignment direction. Process 1400 may include “set linear misalignment” 1474. When one or more pads in the same location of multiple ETOs and in the same dimension and direction have contact, then linear misalignment is indicated, and the misalignment magnitude is as described above is set as the final misalignment of the first ETO that had detected contact or some combination of all ETOs that indicated the contact (such as an average). See bidirectional below for an explanation of ETO probing order.

Process 1400 may include “compute bidirectional misalignment” 1476, which is used when two different pattern pad locations in one or more ETO has contact with the monitoring pad. By one example form, probing the ETOs one by one may proceed by starting from an ETO with a smallest monitoring pad and subsequently testing the ETO with the next larger monitoring pad to determine which ETO reveals a short first, and in turn contact between pads. Once contact and a misalignment is detected, the remaining ETOS with larger monitoring pads should also show a misalignment. In this order, an ETO with a short cannot be missed, and either first occurrences in each dimension (X and Y) are considered, or alternatively, all of the ETOs with shorts should be used to determine the final overlay or misalignment dimension.

Particularly, when starting with the ETOs with the smaller monitoring pads, the first ETO with a short is most likely to be a linear misalignment since a smaller monitoring pad has a greater chance of contacting only one pad. The magnitude of this misalignment is then recorded as the X (or Y) misalignment. Then, when the ETO probing continues with larger monitoring pads, greater chances for bidirectional misalignment occur. In that case, the previous X misalignment signal or magnitude now can be treated as an X component of a final diagonal misalignment. Next then, the system or circuit may compute the magnitude of the other direction magnitude (here being Y). Then the two components may be combined using Pythagorean theorem sqrt(X²+Y²). It should be noted that the two components should be the first component in each direction, and this is true whether or not the two components are obtained by using the same ETO. By a possible alternative, the component magnitudes from different ETOs may each be combined separately such as averaged, and then used to form a final bidirectional component. Many variations can be used.

Process 1400 may include “compute rotational misalignment” 1478, where the contact surface area on all four pattern pads should be, or is assumed to be, substantially the same. Thus, an average of the contact surface areas may be used as a look-up in a look up table for a specific monitoring pad size to determine the amount of rotation. Otherwise, one CSA for each pattern pad being analyzed (here four) may be entered into a look-up table to determine the amount of rotation. It should be noted that the determination of where rotation is clockwise or counter-clockwise is not needed since the size of the rotation angle needed to be detected by four signals showing contact typically will result in a large angular error by the rotation of the monitoring pad that is easily noticed by other detection techniques. Otherwise, when calculating rotation using micro-radians (which is normally expected), the overlay circuits can be probed for translation (X and Y) errors at two opposite corners of a die, and then the probe results may be used to calculate relative rotation between the corners.

As mentioned by one form, the ETO with at least one pattern pad in contact with the monitoring pad that has the largest monitoring pad is used to determine the misalignment. By an alternative approach, each ETO with pads in contact are analyzed, and an average (or some other combination) misalignment distance among the set of ETOs is then used. The misalignment magnitude than may be used to adjust the alignment tools for subsequent bonding of other IC dies and electronic devices.

The result is a substantially fully uniform, electrically active die without any metal free zones (for fiducial purposes herein) for best flexibility and utilization, and without compromising on overlay accuracy.

Referring to FIG. 15, the local test circuits may be arranged on the IC die and electronic device, and particularly constructed as layers within the IC die and electronic device. The local test circuits may have power circuitry to receive power and power up the pads of ETOs in order to electrically activate the ETOs. The local test circuits also may have signal transmission circuitry for transmission of input or output (I/O) signals. A number of different metallization layer, via, and pad arrangements may be used to provide these features. In one example, a package 1500 has an IC die 1502 bonded to an electronic device 1504, such as a die still within, or to remain within, a wafer (D2 W structure), and bonded at a main array and fiducial region. The IC die 1502 may have dielectric material over and around a local test circuit 1512. The local test circuit 1512 may be provided for each ETO on the bonded IC die and other electronic device. The local test circuit 1512 may be coupled to pads 1514 and 1515. It will be understood that pads 1514 and 1515 may represent hundreds or thousands of pads of an array and fiducial region on the IC die 1502. Just for simplicity, pads 1514 and 1515 will be assumed to be fiducial pads of one or more ETOs described above. The local test circuit 1512 may include the layers and levels of dielectric and metallization including vias needed to construct the local test circuit 1512. The fiducial pads 1514 and 1515 coupled to the local test circuit 1512 are either the monitoring pads or pattern pads of one or more ETOs. This architecture related to the local test circuit and its ETO pads is the same or similar for each of the package architectures described below with any of FIGS. 16-20.

The electronic device 1504 may have dielectric material 1506 under and around fiducial pads 1508 aligned with fiducial pads 1514 and 1515 to form the ETOs and also may represent all other pads on an array and fiducial region as described above. An ETO formed by fiducial pads 1508 is coupled to a local test circuit 1510. The electronic device 1504 also may have dielectric and metallization layers (also not shown). In order to provide the power and I/O features, additional interconnect or other type of connection peripheral pads 1518 and 1519 may be provided as part of circuitry, in one example, for drain power voltage (VDD), ground (GND), input/output (I/O) pads, and/or other circuitry as desired, where one pad may be provided for each function. Thus, while two pads 1518 and 1519 are shown, more pads may be present to provide the desired functions.

The peripheral pads 1518 and 1519 are shown on the bonding interface surface 1520 of the electronic device 1504 and may be in many different configurations. Externally, the peripheral pads 1518 and 1519 may be coupled to power pads, vias, interconnects, traces, cables, probe cards, and/or probes external to the IC 1502 and wafer 1504. These power elements may extend into other IC dies mounted on the wafer 1504, and/or a package substrate or host (PCB/mother board, etc.), and then to external power circuits and power supplies, I/O analysis equipment (oscilloscope, microcontroller boards, digital acquisition cards, and so forth), or other external equipment or circuits with temporary coupling to the peripheral pads for external analysis units.

By one form, the peripheral pads 1518 and 1519 each may be coupled to the short unit, decoder, control, and so forth of the post-bond misalignment device 800 (FIG. 8) when provided externally to the package 1500. Otherwise, as described above, such circuitry may be permanent circuitry on the local test circuit 1512, within the IC die 1502, and/or on other part of the package 1500.

Internally, the peripheral pads 1518 and 1519 may be coupled to the local test circuits 1510 to provide current and GND return path and input/output signals. In the case when a simple open/short circuit detection of the pads is used to determine the misalignment direction, the peripheral pads can also connect directly to the alignment pads 1514, 1515, and 1508.

Other traces and vias on the IC die 1502 and wafer 1504 (not shown) may be coupled to the peripheral pads as well in order to provide power to the IC die 1502 when the peripheral pads are only on the wafer 1504 so that the local test circuit 1512 (which may be or include a built-in self-test (BIST) circuit) can be powered up and can transmit confirmation signals to the I/O pads where test equipment may be connected. Otherwise, backside test pads could be added to the IC die 1502 to provide separate power (VDD) to the local test circuit 1512.

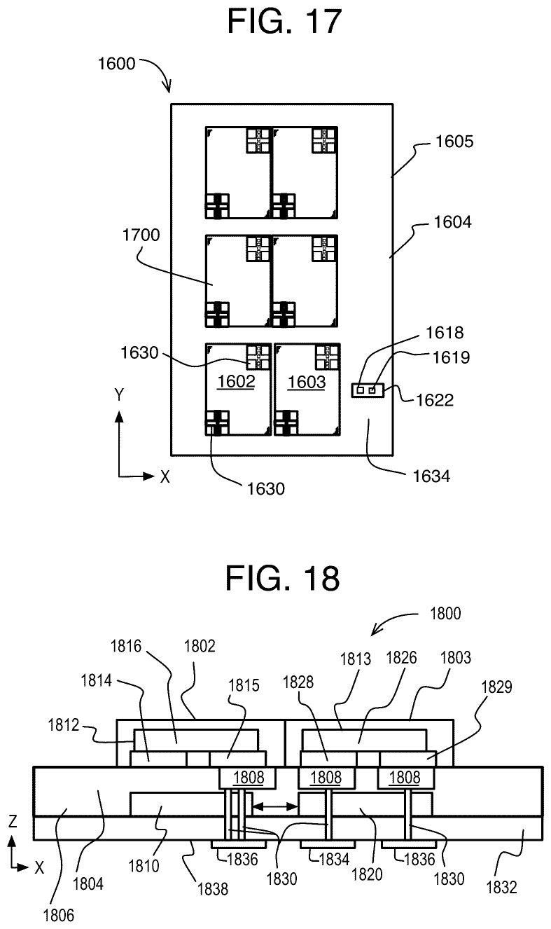

Referring to FIGS. 16-17, package 1600 locates the peripheral pads in a frame 1634 of an electronic device 1604, such as a wafer (and shown in (X-Y) plan view on FIG. 17), in order to avoid placing the peripheral pads on active regions of a wafer that could reduce the useful area of the wafer. Specifically, package 1600 has a similar architecture to package 1500 so that features that are the same or similar have similar numbering. Here, for package 1600, however, a second IC die 1603 has a local test circuit 1626 electrically connected to active pads 1628 and 1629 that represent hundreds or thousands of pads, and may include fiducial pads. The local test circuit 1626 may be adjacent to a local test circuit 1612 and with similar structure as local test circuit 1512. In this case, however, the electronic device 1604 also has an additional local text circuit 1620 similar to that of the other local test circuits, and is coupled to fiducial pads 1608 aligned with fiducial pads 1628 and 1629 for testing for example.

Also, the electronic device 1604 may have a frame test overlay 1622 coupled to frame test circuitry 1623 to couple additional power and/or I/O pads 1618 and 1619 forming the frame test overlay 1622 to local test circuits 1610 and 1620. The frame test circuitry 1623 also may include a small digital controller that polls more than one local test circuit and collects information from the local test circuits regarding resistivity and capacitance measurements. The frame test circuitry 1622 also may be responsible to provide the output from the test equipment, and may even control power on/or power down of the individual local test circuits 1610, 1620, and 1612, and 1626.

The additional pads 1618 may provide an interface for VDD and GND functions, and additional pad 1619 may provide I/O transmissions. By one, form, rather than having one or more of the additional pads for each ETO, the pads may be shared by the ETOs 1610 and 1620 in this example. Thus, the local circuits of the ETOs each may be coupled (as shown by two-way arrows) in parallel or series to receive power to drive the active fiducials and transmit or receive signals. The I/O pad 1619 may be used with a multiplexed and serialized operation to test all fiducials within a frame.

Referring to FIG. 17, in order to avoid occupying fiducial or main array area on the electronic device 1604 in this example, the additional pads 1618 and 1619 of the frame test overlay 1622, and the frame test circuitry 1623 as well, may be located on the frame 1634 of the electronic device 1604 that is external to an array of dies (or die arrays to be bonded to IC dies) 1700. The IC dies 1700 include IC dies 1602 and 1603 (each shown with two fiducial regions 1630, although one or four such regions may be provided on each array) and on a reticle 1605. Only one reticle 1605 is shown but the wafer 1604 may have a number of reticles. Each reticle 1605 may have one or more IC dies 1700 and the frame 1634 that provides the frame overlay 1622 and frame pads 1618 and 1619.

Referring to FIG. 18 for another approach, a package 1800 may have an IC die 1802 bonded by a main array (not shown) to an electronic device 1804 such as another IC die on a wafer. The components of the package 1800 that are similar to that on packages 1500 and 1600 are numbered similarly and need not be described again. In this alternative, through silicon vias (TSVs) 1830 extending through a sacrificial redistribution layer (RDL) 1832, formed of a dielectric material, can be used to probe the ETOs formed by the aligned fiducial pads 1814, 1815, 1808, 1828, and 1829. Such a sacrificial layer 1832 may be used on the either a top die or bottom electronic device or both. Specifically, TSVs 1830 may be coupled to pads 1808 and extend downward, in order from top to bottom as shown on package 1800, first through dielectric and/or metallization layers of the electronic device 1804 in this example. Second, the TSV 1830 may extend downward through, and couple to, local test circuits 1810 and 1820. Third, extend downward through the sacrificial layer 1832, and finally to sacrificial pads 1834 and 1836 on an external side 1838 of the sacrificial layer 1832. The sacrificial pads 1836 may be provided for VDD and GND power functions, while sacrificial pad 1834 may be provided for I/O signal transmissions. The sacrificial pads 1834 and 1836 may be provided in any convenient and efficient arrangement and may be shared by ETOs and local test circuits as described with package 1600 with traces and vias electrically coupling the ETOs to shared sacrificial pads 1834 or 1836. Thus, the local test circuits 1811 and 1821 may couple to pads 1808 on vias or other metallization layer that is separate from the TSVs 1830, and use the TSVs 1830 merely to couple to sacrificial pads 1836 and 1834.

The sacrificial RDL layer 1832 may have a number of dielectric and metallization layers to provide circuitry among the ETOs formed by the pads, local circuits 1810 and 1820, and TSVs 1830 rather than having such circuitry permanently on the electronic device 1804. The sacrificial RDL layer 1832 also may have circuitry for other purposes including for testing active circuitry or test devices. Once the post-bond misalignment testing is complete, the sacrificial RDL layer may be removed by etching, or laser debond. This may remove the sacrificial pads 1836 and 1834 as well as a portion of the TSVs 1830 that extend through the sacrificial RDL layer 1832. The remaining ends of the TSVs 1830 may be plated with a pad, but may not be used in the final completed package. Otherwise, after removing the sacrificial layer 1832, new first level interconnect (FLI) pads may be deposited over the caps of the TSVs 1830. This arrangement avoids the use of a periphery or frame pads for the power and I/O functions, and has no array or fiducial region area overhead that would reduce useful active pad area on an IC die or electronic device.

Referring to FIG. 19 for another alternative, wireless power transfer and/or I/O signal transmission may be used rather than, or in addition to, using the peripheral or sacrificial pads of packages 1500, 1600, and 1800. In this example, a package 1900 has an IC die 1902 bonded to an electronic device 1904, such as a die on a wafer. The electronic device 1904 may have one or more substrate dielectric material layers 906 surrounding and alternating with metallization layers, and the IC die 1902 may have the same types of layers with different architecture configurations. The IC die 1902 may have a local test circuit 1912 coupled to one or more fiducial pads 1914 forming ETOs. Similarly, the electronic device 1904 has a local test circuit 1910 coupled to one or more fiducial pads 1908 to form an ETO and electrically activate those pads.

The package 1900 may integrate a wireless power transfer function into other fiducial (or main array) pads 1918 and 1920 in order to be able to perform testing on the fly. This arrangement may enable a better understanding of assembly quality and performance very early in the manufacturing process.

The wireless power transfer with inline monitoring architecture may be used very sparsely on a wafer so as not to reduce the usefulness of the package but still can prove valuable from a yield and cost reduction perspective. The wireless power transfer with integrated test circuits should be at a very low power level, such as a range of nW (nanowatts) to uWatts (microwatts) of power, that still is sufficient to monitor the resistance or capacitance among assembled ETO pads.

Such wireless power circuits that can be used to power on the circuitry driving the ETOs and in turn results may be output by RF transmission (e.g. backscattering techniques). For this RF implementation, the antenna 1922 may be embedded within the dielectric material 1906 of the IC die. Specifically, fiducial pads 1918 of a fiducial region may be provided on the IC die 1902 and a wire 1924 coupled to the pads 1918 (or just the wire) may be arranged to be a wireless power antenna. Otherwise, lower metallization layers or levels below the fiducial metal layer or level may form an RF antenna that can absorb incoming radiation through the external or top side 1930 of the IC die 1902, although RF transmission through the wafer 1904 could be used as well. The antenna 1922 may be made of copper and formed by known deposition techniques.

The antenna 1922 may be provided as a rectangular or other shape patch, which may extend out of the fiducial region. For example for RF power using 300 GHz, such rectangular patches on-chip can range from a size of 500×200 micrometers to 200×200 micrometers. By increasing the frequency to 600 GHz, antenna size may further reduce to less than 250×100 micrometers. Here, however, due to the typical maximum fiducial area size, such as equal to or smaller than 100×100 micrometers, the antenna 1922 may be limited to over the fiducial region, and the RF frequency operations may be in the 100-1000 GHz range. In this case, when the pitch is 2 micrometers in the fiducial region for example, then the antenna 1922 may cover an area of 50×50 pads, 100×100 pads, or 200×200 pads, all within the area dedicated for the fiducial. Other arrangements or techniques that can be used for the antenna 1922 may include monopole antennas, dipole antennas, folded monopole/dipole antennas, slot antennas, bowtie antennas and so forth. The radiation (mmWave/THz) can be generated at the assembly equipment using commercial mmWave/THz sources and antennas.

With this arrangement, it will be understood that the antenna 1922 may be shared among all local test circuits of the ETOs. The antenna may be integrated in the frame area as well. The antenna 1922 collects the RF power, and the circuit connected to the antenna 1922 may convert the RF received power to DC power. Such a circuit may have an RF-DC converter (based on a rectifier topology) with a 10% efficiency by one example. This DC power then may be fed to the local test circuits and the frame circuits if present. With this arrangement, no need exists to use an external power supply through VDD and GND pads.

In operation, an RF source 1950 may transmit the RF radiation to the antenna 1922, and the local test circuit 1912 on the IC die 1902 may be coupled to the wire or coil 1926 or pads 1918 of the antenna 1922 to receive power from, and probe, the fiducial pads 1914 of the ETOs, and to transmit output signals. Likewise, local test circuits 1910 on the electronic device 1904 may receive power from pads 1918 bonded to the pads 1920. The local test circuit 1910 may be coupled to the pads 1920 to probe fiducial pad 1908 and output misalignment signals.

By one approach, in addition to using wireless power transmission for low power local test circuits, an additional antenna 1926 may be used to transmit and receive I/O signals. One way to accomplish this may be to integrate the second antenna 1926 within the fiducial area which will be responding to modulated I/O signals. Such an arrangement may have high frequency rectification that should be accompanied with some accurate phase control. In this case then, the second antenna 1926 should be receiving the incoming RF power wave as needed. Such antenna 1926 can be the same or similar configuration as the power antenna 1922 mentioned above, and should provide increased performance and efficiency.

By an alternative form, the same single antenna 1922 used to power up the ETOs and fiducial pads also may be used to transmit I/O signals by backscattering the information back to the RF source 1950 and by modulating an incident signal to encode the measured data from the integrated test circuit. By one example, this can be accomplished by using one polarization of an RF wave (vertical) to downlink and power while using the other polarization (e.g. horizontal) for uplink (to send data back to the post-bond misalignment device, such as device 800 (FIG. 8) for example).

Referring to FIG. 20, similarly to RF wireless power, a photovoltaic system may be used instead of RF transmission to power up the integrated local test circuits on a package 2000. A light projector 2050 can be aimed at silicon integrated PN-junction photodiodes 2024 on package 2000 to capture incoming light and convert the light into electrical current. Specifically, package 2000 may have the same or similar structure as package 1900 where many components are the same or similar and are therefore numbered the same or similarly. Further description of these components is not necessary. The package 2000 also has an IC die 2002 with one or more photodiodes 2024, or an array or bank of such diodes, integrated into a top surface 2030 of the IC die and underneath (or over) ETO pads 2018 and 2020. Again, a DC-DC converter may generate the desired voltage for local (and frame if present) test circuits after converting the light to energy. The power may be provided to the local test circuit 2018 and/or pads 2018 and 2019 directly.

The photodiodes 2024 can be backside illuminated so that light captured by the photodiodes 2024 can convert the light into current, which can then be stored in a capacitive bank (not shown) or be provided directly to pads 2018 coupled to a local test circuit 2012. The local test circuit 2012 then can charge the fiducial pads 2014 of the ETOs and probe the pads 2014 for electrical levels. Likewise, pads 2020 bonded to pads 2018 receive charge from pads 2018 and provide the charge to a coupled local test circuit 2010 in order to charge and probe fiducial pads 2008.

It should be noted that any of the packages 1500 to 2000 above may have fiducial regions and fiducial region columns with metallization and are completely free of KOZs due to fiducial-related purposes (KOZs may still exist in the fiducial reason for other purposes).

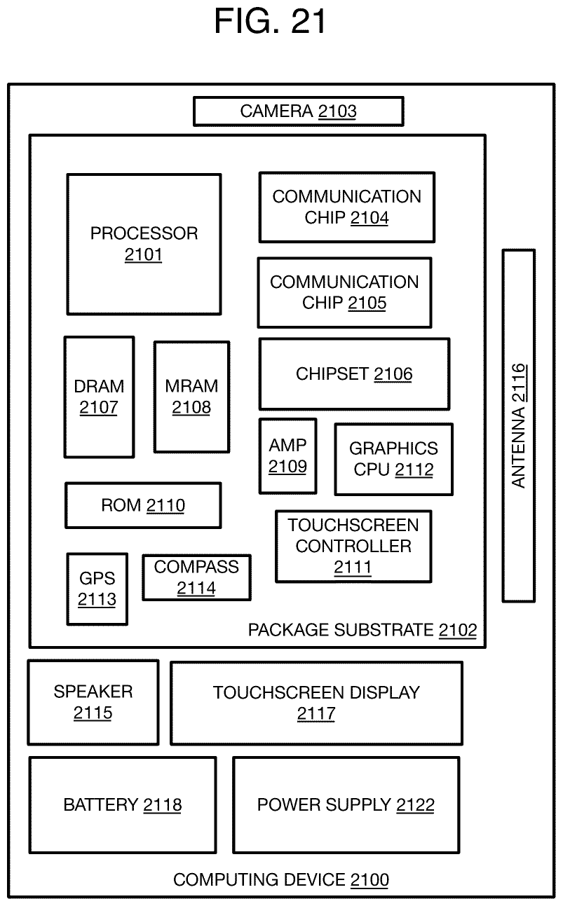

Referring to FIG. 21, a functional block diagram of an electronic computing device 2100 is in accordance with at least one of the implementations herein. Device 2100 further includes a package substrate 2102 hosting a number of components, such as, but not limited to, a processor 2101 (e.g., an applications processor). Processor 2101 may be physically and/or electrically coupled to package substrate 2102. In some examples, processor 2101 is within a composite IC chip structure including IC dies bonded to each other with fiducial regions as described elsewhere herein, and may include a chiplet bonded to a host IC chip, for example. Processor 2101 may be implemented with circuitry in any of the IC dies. In general, the term “processor” or “microprocessor” may refer to any device or portion of a device that processes electronic data from registers and/or memory to transform that electronic data into other electronic data that may be further stored in registers and/or memory.

In various examples, one or more communication chips 2104 and 2105 may also be physically and/or electrically coupled to the package substrate 2102. In further implementations, communication chips 2104 and 2105 may be part of processor 2101. Depending on its applications, computing device 2100 may include other components that may or may not be physically and electrically coupled to package substrate 2102. These other components include, but are not limited to, volatile memory (e.g., DRAM 1207), non-volatile memory (e.g., ROM 2110), flash memory (e.g., NAND or NOR), magnetic memory (MRAM 2108), a graphics processor 2112, a digital signal processor, a crypto processor, a chipset 2106, an antenna 2116, touchscreen display 2117, touchscreen controller 2111, battery 2118, power supply 2122, audio codec, video codec, power amplifier 2109, global positioning system (GPS) device 2113, compass 2114, accelerometer, gyroscope, speaker 2115, camera 2103, and mass storage device (such as hard disk drive, solid-state drive (SSD), compact disk (CD), digital versatile disk (DVD), and so forth), or the like. In some exemplary implementations, at least two of the functional blocks noted above are within a composite IC chip structure including bonded IC dies with fiducial regions and/or a chiplet bonded to a host IC chip, for example as described elsewhere herein. For example, processor 2101 may be implemented with circuitry in an IC die, and an electronic memory (e.g., MRAM 2108 or DRAM 2107) may be implemented with circuitry in a second of the IC dies, including an IC chip and chiplet.

Communication chips 2104 and 2105 may enable wireless communications for the transfer of data to and from the computing device 2100. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some implementations they might not. Communication chips 2104 and 2105 may implement any of a number of wireless standards or protocols. As discussed, computing device 2100 may include a plurality of communication chips 2104 and 2105. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

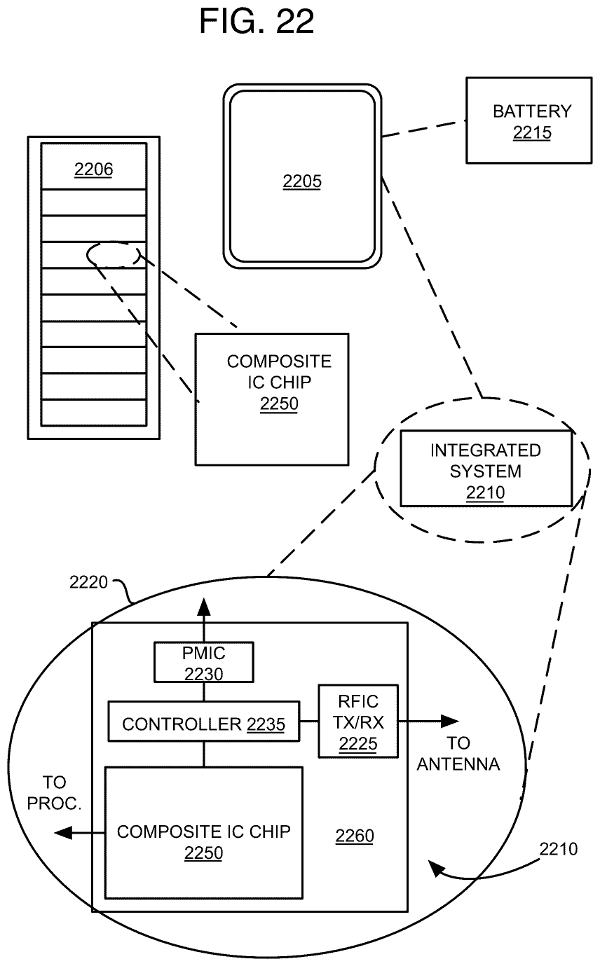

Referring to FIG. 22, a mobile computing platform 2205 and a data server machine 2206 employs an IC device comprising at least one IC die with a fiducial region as described above. Computing device 2200 may be found inside platform 2205 or server machine 2206, for example. The server machine 2206 may be any commercial server, for example including any number of high-performance computing platforms disposed within a rack and networked together for electronic data processing, which in the exemplary implementation includes a composite IC chip 2250 that includes IC dies bonded to each other, and/or a chiplet bonded to a host IC chip, for example, and with fiducials as described elsewhere herein. The mobile computing platform 2205 may be any portable device configured for each of electronic data display, electronic data processing, wireless electronic data transmission, or the like. For example, the mobile computing platform 2205 may be any of a tablet, a smart phone, laptop computer, etc., and may include a display screen (e.g., a capacitive, inductive, resistive, or optical touchscreen), a chip-level or package-level integrated system 2210, and a battery 2215.

Whether disposed within the integrated system 2210 illustrated in the expanded view 2220, or as a stand-alone package within the server machine 2206, composite IC chip 2250 may include IC dies bonded together by using a fiducial region described above, and may be a chiplet bonded to a host IC chip, for example. Composite IC chip 2250 may be further coupled to a host substrate 2260, along with, one or more of a power management integrated circuit (PMIC) 2230, RF (wireless) integrated circuit (RFIC) 2225 including a wideband RF (wireless) transmitter and/or receiver (TX/RX) (e.g., including a digital baseband and an analog front end module further comprises a power amplifier on a transmit path and a low noise amplifier on a receive path), and a controller 2235. PMIC 2230 may perform battery power regulation, DC-to-DC conversion, etc., and so has an input coupled to battery 2215 and with an output providing a current supply to other functional modules. As further illustrated, in the exemplary implementation, RFIC 2225 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 4G, and beyond.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

Also, it is understood that the subject matter of the present description is not necessarily limited to specific applications illustrated in FIGS. 1-22. The subject matter may be applied to other electronic devices and assembly applications, as well as any appropriate electronic application, as will be understood to those skilled in the art.

The following examples pertain to further implementations. Specifics in the examples may be used anywhere in one or more implementations.

In example 1, an integrated circuit (IC) device, comprises an array comprising rows and columns of conductive interconnect pads; and at least one optical alignment fiducial region distinct from the array and comprising a fiducial pattern, wherein the fiducial pattern comprises a first group of pads contiguous to a second group of pads, wherein a width of a space between nearest pads of the first and second groups is wider than the spaces between pads within each group when measured in a same dimension.

In example 2, the subject matter of example 1, wherein the fiducial pattern comprises having the pads within the groups spaced apart from each other up to a maximum amount so that the groups appear as a single continuous shape in an image and having the groups spaced apart from each other down to a minimum amount so that the groups appear segmented from each other in the image.

In example 3, the subject matter of example 1 or 2, wherein the width of the space between pads within at least one of the groups is less than a diffraction-limited resolution of a light-based imaging device to be used to capture an image of the fiducial pattern.

In example 4, the subject matter of any one of examples 1 to 3, wherein the width of the space between the groups is at least a diffraction-limited resolution of a visible or NIR light wavelength imaging device to be used to capture an image of the fiducial pattern.

In example 5, the subject matter of any one of examples 1 to 4, wherein the fiducial region comprises a fiducial pitch between consecutive pads across the space between the first and second groups, and wherein the fiducial pitch is at least a length of a diffraction-limited resolution of a light-based imaging device plus the width of one of the pads, and wherein a first pitch between pads within the groups is less than the diffraction-limited resolution plus the width of one of the pads.

In example 6, the subject matter of example 5, wherein the fiducial region has rows and columns of pads continued from the array with the fiducial pitch and spaces between groups being formed by at least part of a single column of pads or part of a single row of pads or both being omitted within the fiducial region.

In example 7, the subject matter of any one of examples 1 to 6, wherein a fiducial region replaces only two diagonally opposite corners or opposite side portions of the array.

In example 8, the subject matter of any one of examples 1 to 7, wherein the device comprises a margin free of pads between the at least one fiducial region and the array, wherein the margin comprises a width at least as wide as a diffraction-limited resolution of the optical system to be used to capture an image of the fiducial pattern.

In example 9, the subject matter of any one of examples 1 to 8, wherein the at least one fiducial region is formed as a three-dimensional space extending through the IC device and is free of any fiducial metal keep-out-zone.

In example 10, the subject matter of any one of examples 1 to 9, wherein the array is a first array bonded to a second array of an electronic device facing the integrated circuit device, wherein one of the first or second arrays comprises a plurality of alignment monitoring pads spaced from each other within the array or fiducial region or both, and each monitoring pad having a bonding interface surface with a surface area or shape different than that of the other monitoring pads.

In example 11, the subject matter of example 10, wherein the other of the first and second arrays comprises a plurality of electrical testing overlay pad patterns each having multiple pads, and wherein each monitoring pad is horizontally aligned with a different one of the electrical testing overlay pad patterns.

In example 12, the subject matter of example 11, wherein the monitoring pads are each disposed amid at least four pads forming each electrical testing overlay pad pattern so that the outer boundary of the monitoring pads are each a respective different horizontal distance to the pads of the electrical testing overlay patterns.

In example 13, the subject matter of example 11, wherein the device comprises at least one local test circuit to provide electricity to, and monitor the electrical flow of, at least one of the electrical testing overlay, wherein the at least one local test circuit comprises an antenna.

In example 14, a method of manufacturing an electronic package comprises receiving an integrated circuit (IC) die with a first array of conductive interconnect pads and at least one fiducial region distinct from the first array and having a fiducial pattern formed by conductive interconnect pads, wherein the pads are formed into groups within the fiducial pattern, and a space between pads at the boundary of contiguous groups is wider than a space between pads within the individual groups and in a same dimension; obtaining an image of the at least one fiducial region and an image of at least one corresponding fiducial region of a second array of an electronic device to be bonded to the first array; aligning the fiducial regions of the IC die and the electronic device to each other using the images to align the pads of the first and second arrays; and bonding the aligned pads of the first and second arrays together.

In example 15, the subject matter of example 14, wherein the IC die comprises at least one metallization layer with metal that extends under the spaces between groups of the at least one fiducial region.

In example 16, the subject matter of example 14 or 15, wherein the method comprises measuring post-bond pad misalignment comprising electrically activating a plurality of spaced monitoring pads each having a top bonding surface of a different size or shape, and each being aligned with a different one of a plurality of electrical testing overlay pad patterns each having multiple pads; and determining whether or not a monitoring pad is in contact with at least one of the respective aligned multiple pads.

In example 17, the subject matter of example 16, wherein the method comprises determining an amount of resistance or capacitance due to the contact; and determining a misalignment magnitude of the monitoring pad depending on the amount.

In example 18, the subject matter of example 16, wherein the monitoring pads are only positioned within the at least one fiducial region.

In example 19, a system comprises an integrated circuit (IC) device, comprises an array comprising rows and columns of conductive interconnect pads; and at least one optical alignment fiducial region distinct from the array and comprising a fiducial pattern, wherein the fiducial pattern comprises a first array of pads contiguous to a second array of pads, wherein nearest pads of the first and second array define space between the first and second arrays and are a fiducial pitch apart along a dimension, wherein a width of the space is wider than spaces between pads within the first and second arrays and along the dimension.

In example 20, the subject matter of example 19, wherein the width of the space is at least partly based on a numerical aperture value of a visible or near infra-red (NIR) light wavelength imaging device to be used to detect the fiducial pattern.

In example 21, the subject matter of example 19 or 20, wherein the spacing between the first and second arrays is at least 1.1 micrometers wide.

In example 22, the subject matter of any one of examples 19 to 21, wherein the spacing between the first and second arrays is in a range of 400 nanometers to 6 micrometers wide depending on a numerical aperture value of a visible light wavelength imaging device to be used to detect the fiducial pattern.

In example 23, the subject matter of any one of examples 19 to 22, wherein the spacing between the first and second arrays and the spacing between pads within the first and second array is at least partly based on a diffraction-limited resolution of a visible light wavelength imaging device to be used to detect the fiducial pattern.

In example 24, the subject matter of any one of examples 19 to 23, wherein the IC die has four of the fiducial regions each replacing a corner of the array and at least one metallization layer having metal extending under each fiducial region.

In example 25, the subject matter of any one of examples 19 to 24, comprising an electronic device having a fiducial region to bond to the fiducial region of the IC die; and an antenna coil fiducial in at least one of the fiducial regions and being disposed contiguous to at least one of the first and second pad arrays in the fiducial region.

In example 26, a device, apparatus, or system includes means to perform a method according to any one of the above implementations.

In example 27, at least one machine readable medium includes a plurality of instructions that in response to being executed on a computing device, cause the computing device to perform a method according to any one of the above implementations.

It will be recognized that the disclosures herein are not limited to the implementations so described, but can be practiced with modification and alteration without departing from the scope of the appended claims. For example, the above implementations may include specific combination of features. However, the above implementations are not limited in this regard and, in various implementations, the above implementations may include undertaking only a subset of such features, undertaking a different order of such features, undertaking a different combination of such features, and/or undertaking additional features than those features explicitly listed. The scope of the assemblies, devices, and methods disclosed herein should, therefore, be determined with reference to the appended claims, along with the full scope of equivalents to which such claims are entitled.

What is claimed is:

1. An integrated circuit (IC) device, comprising:
an array comprising rows and columns of conductive interconnect pads; and
at least one optical alignment fiducial region distinct from the array and comprising a fiducial pattern, wherein the fiducial pattern comprises a first group of pads contiguous to a second group of pads, wherein a width of a space between nearest pads of the first and second groups is wider than the spaces between pads within each group when measured in a same dimension.

2. The device of claim 1 wherein the fiducial pattern comprises having the pads within the groups spaced apart from each other up to a maximum amount so that the groups appear as a single continuous shape in an image and having the groups spaced apart from each other down to a minimum amount so that the groups appear segmented from each other in the image.

3. The device of claim 1 wherein the width of the space between pads within at least one of the groups is less than a diffraction-limited resolution of a light-based imaging device to be used to capture an image of the fiducial pattern.

4. The device of claim 1 wherein the width of the space between the groups is at least a diffraction-limited resolution of a visible or NIR light wavelength imaging device to be used to capture an image of the fiducial pattern.

5. The device of claim 1 wherein the fiducial region comprises a fiducial pitch between consecutive pads across the space between the first and second groups, and wherein the fiducial pitch is at least a length of a diffraction-limited resolution of a light-based imaging device plus the width of one of the pads, and wherein a first pitch between pads within the groups is less than the diffraction-limited resolution plus the width of one of the pads.

6. The device of claim 5 wherein the fiducial region has rows and columns of pads continued from the array with the fiducial pitch and spaces between groups being formed by at least part of a single column of pads or part of a single row of pads or both being omitted within the fiducial region.

7. The device of claim 1 wherein a fiducial region replaces only two diagonally opposite corners or opposite side portions of the array.

8. The device of claim 1 comprising a margin free of pads between the at least one fiducial region and the array, wherein the margin comprises a width at least as wide as a diffraction-limited resolution of the optical system to be used to capture an image of the fiducial pattern.

9. The device of claim 1 wherein the at least one fiducial region is formed as a three-dimensional space extending through the IC die and is free of any fiducial metal keep-out-zone.

10. The device of claim 1 wherein the array is a first array bonded to a second array of an electronic device facing the integrated circuit device, wherein one of the first or second arrays comprises a plurality of alignment monitoring pads spaced from each other within the array or fiducial region or both, and each monitoring pad having a bonding interface surface with a surface area or shape different than that of the other monitoring pads.

11. The device of claim 10 wherein the other of the first and second arrays comprises a plurality of electrical testing overlay pad patterns each having multiple pads, and wherein each monitoring pad is horizontally aligned with a different one of the electrical testing overlay pad patterns.

12. The device of claim 11 wherein the monitoring pads are each disposed amid at least four pads forming each electrical testing overlay pad pattern so that the outer boundary of the monitoring pads are each a respective different horizontal distance to the pads of the electrical testing overlay patterns.

13. The device of claim 11 comprising at least one local test circuit to provide electricity to, and monitor the electrical flow of, at least one of the electrical testing overlays.

14. A method of manufacturing an electronic package comprising:
receiving an integrated circuit (IC) die with a first array of conductive interconnect pads and at least one fiducial region distinct from the first array and having a fiducial pattern formed by conductive interconnect pads, wherein the pads are formed into groups within the fiducial pattern, and a space between pads at the boundary of contiguous groups is wider than a space between pads within the individual groups and in a same dimension;
obtaining an image of the at least one fiducial region and an image of at least one corresponding fiducial region of a second array of an electronic device to be bonded to the first array;
aligning the fiducial regions of the IC die and the electronic device to each other using the images to align the pads of the first and second arrays; and
bonding the aligned pads of the first and second arrays together.

15. The method of claim 14 wherein the IC die comprises at least one metallization layer with metal that extends under the spaces between groups of the at least one fiducial region.

16. The method of claim 14 comprising measuring post-bond pad misalignment comprising electrically activating a plurality of spaced monitoring pads each having a top bonding surface of a different size or shape, and each being aligned with a different one of a plurality of electrical testing overlay pad patterns each having multiple pads; and determining whether or not a monitoring pad is in contact with at least one of the respective aligned multiple pads.

17. The method of claim 16 comprising determining an amount of resistance or capacitance due to the contact; and determining a misalignment magnitude of the monitoring pad depending on the amount.

18. The method of claim 16 wherein the monitoring pads are only positioned within the at least one fiducial region.

19. A system comprising:
an integrated circuit (IC) device, comprising:
an array comprising rows and columns of conductive interconnect pads; and
at least one optical alignment fiducial region distinct from the array and comprising a fiducial pattern, wherein the fiducial pattern comprises a first array of pads contiguous to a second array of pads, wherein nearest pads of the first and second array define space between the first and second arrays and are a fiducial pitch apart along a dimension, wherein a width of the space is wider than spaces between pads within the first and second arrays and along the dimension.

20. The system of claim 19 wherein the width of the space is at least partly based on a numerical aperture value of a visible or NIR light wavelength imaging device to be used to detect the fiducial pattern.

21. The system of claim 19 wherein the spacing between the first and second arrays is at least 1.1 micrometers wide.

22. The system of claim 19 wherein the spacing between the first and second arrays is in a range of 400 nanometers to 6 micrometers wide depending on a numerical aperture value of a light-based imaging device to be used to detect the fiducial pattern.

23. The system of claim 19 wherein the spacing between the first and second arrays and the spacing between pads within the first and second array is at least partly based on a diffraction-limited resolution of a light-based imaging device to be used to detect the fiducial pattern.

24. The system of claim 19 wherein the IC die has four of the fiducial regions each replacing a corner of the array and at least one metallization layer having metal extending under each fiducial region.

25. The system of claim 19 comprising an electronic device having a fiducial region to bond to the fiducial region of the IC die; and an antenna coil fiducial in at least one of the fiducial regions and being disposed contiguous to at least one of the first and second pad arrays in the fiducial region.
